(19) United States
(12) Patent Application Publication
(10) Pub. No.: US 2025/0170800 A1
(43) Pub. Date: May 29, 2025

(54) PRODUCTION METHOD FOR HOLLOW STRUCTURE, LAMINATE

(71) Applicant: TOKYO OHKA KOGYO CO., LTD., Kawasaki-shi (JP)

(72) Inventors: Shota KATAYAMA, Kawasaki-shi (JP); Kenichi YAMAGATA, Kawasaki-shi (JP); Hirofumi IMAI, Kawasaki-shi (JP)

(21) Appl. No.: 18/836,505

(22) PCT Filed: Feb. 16, 2023
(86) PCT No.: PCT/JP2023/005464

§ 371 Date: Aug. 7, 2024

(30) Foreign Application Priority Data
Feb. 17, 2022 (JP) 2022-023281

(51) Int. Cl. B32B 7/05; B32B 27/08; B32B 27/36; B32B 37/24; B32B 38/00; B32B 38/10; B81C 1/00; G03F 7/028; H03H 9/64

(52) U.S. Cl. CPC B32B 7/05; B32B 27/08; B32B 27/36; B32B 37/24; B32B 38/0008; B32B 38/10; B81C 1/00333; G03F 7/028; B32B 2037/243; B32B 2250/244; B32B 2255/10; B32B 2255/26; B32B 2307/412; B32B 2363/00; B32B 2367/00; B32B 2457/00; H03H 9/64

(57) ABSTRACT

A production method for a hollow structure consisting of a concave portion and a top plate portion that blocks an opening surface of the concave portion is adopted, the production method including forming at least one of a side wall or the top plate portion by using a laminate of a support and a resist layer, in which the support consists of a polyethylene terephthalate film having a light transmittance of 85% or more at a wavelength of 365 nm and a haze value of 1.0% or less when irradiated with light having a wavelength of 365 nm, the resist layer consists of a photosensitive layer formed of a negative photosensitive composition, and an operation of exposing the resist layer via the support and developing the laminate after the exposure with a developing solution containing an organic solvent to form a negative pattern. According to this production method, when the side wall or the top plate portion of the hollow structure is formed, it is possible to further improve lithography characteristics (shape and defect reduction) of a pattern, and the hollow structure can be stably produced.

### TECHNICAL FIELD

The present invention relates to a production method for a hollow structure and a laminate useful for the production method.

Priority is claimed on Japanese Patent Application No. 2022-023281, filed Feb. 17, 2022, the content of which is incorporated herein by reference.

### BACKGROUND ART

In recent years, development of microelectronic devices such as a surface acoustic wave (SAW) filter has been promoted. A package encapsulating such an electronic device has a hollow structure for ensuring propagation of the surface acoustic wave and mobility of movable members in the electronic device.

A photosensitive composition is used to form the above-described hollow structure, and a package is produced by molding the photosensitive composition while keeping a wiring board on which electrodes are formed hollow.

For example, Patent Document 1 discloses a production method for a hollow structure including a hollow portion consisting of an element mounted on a substrate, a side wall provided on an upper portion of the substrate to surround an outer periphery of the element, and a top plate provided to be in contact with an upper surface of the side wall and covers an upper portion of the element, and a production method for a hollow package in which the hollow structure is sealed.

The above-described hollow structure is produced as follows,

A dry film resist is used, in which a base film (support), a photosensitive layer, and a cover film are laminated in this order, and then the cover film is peeled off to be laminated on a substrate, perform selective exposure, post-exposure baking, development, and heat treatment, so that the side wall is produced.

Next, a cover film is peeled off from the dry film resist and laminated on the substrate on which the side wall has been produced, a top plate portion is produced by performing selective exposure, post-exposure baking, development, and hard baking treatment, so that the hollow structure having a hollow portion is produced.

### CITATION LIST

### Patent Document

### [Patent Document 1]

PCT International Publication No. WO2020/137610

### SUMMARY OF INVENTION

### Technical Problem

In the production of the above-described hollow structure, in a case where the hollow portion is molded, there is an issue that a film-like top plate portion is likely to be deformed by baking treatment.

In addition, as miniaturization and high density of an electronic component having a hollow structure are further advanced, in a formation of the hollow portion, it is important to form a pattern having fine dimensions. On the other hand, in the photosensitive compositions in the related art, such as those described in Patent Document 1, further improvement in lithography characteristics of a pattern is required.

The present invention has been made in view of the above-described circumstances, and an object of the present invention is to provide a production method for a hollow structure and a laminate useful for the production method for a hollow structure, in which lithography characteristics of a pattern can be further improved when a side wall or a top plate portion of the hollow structure is formed, and in which the hollow structure can be stably produced.

### Solution to Problem

In order to solve the above-described problem, the present invention employs the following configurations.

That is, a first aspect of the present invention relates to a production method for a hollow structure consisting of a concave portion that is surrounded by a substrate and a side wall formed on the substrate and a top plate portion that blocks an opening surface of the concave portion, the production method including: a step of obtaining the concave portion in which the side wall is formed on the substrate; and a step of obtaining the hollow structure by forming the top plate portion on the side wall, in which at least one of the side wall or the top plate portion is formed by using a laminate of a support and a resist layer, the support consists of a polyethylene terephthalate film having a light transmittance of 85% or more at a wavelength of 365 nm and a haze value of 1.0% or less when irradiated with light having a wavelength of 365 nm, the resist layer consists of a photosensitive layer formed of a negative photosensitive composition, and when the at least one of the side wall or the top plate portion is formed by using the laminate, an operation of exposing the resist layer via the support and developing the laminate after the exposure with a developing solution containing an organic solvent to form a negative pattern is performed.

A second aspect of the present invention relates to a laminate of a support and a resist layer, in which the support consists of a polyethylene terephthalate film having a light transmittance of 85% or more at a wavelength of 365 nm and a haze value of 1.0% or less when irradiated with light having a wavelength of 365 nm, the resist layer consists of a photosensitive layer formed of a negative photosensitive composition, and the laminate is used for producing a hollow structure consisting of a concave portion that is surrounded by a substrate and a side wall formed on the substrate and a top plate portion that blocks an opening surface of the concave portion.

### Advantageous Effects of Invention

According to the present invention, a production method for a hollow structure and a laminate useful for the production method can be provided, in which when a side wall or a top plate portion of a hollow structure is formed, it is possible to further improve the lithography characteristics of a pattern, and the hollow structure can be stably produced.

### BRIEF DESCRIPTION OF DRAWINGS

FIG. 1 is a schematic view showing a step (i) in one embodiment of a production method for a hollow structure, and is a side cross-sectional view showing an example of a substrate having a concave portion on a surface.

FIG. 2A to FIG. 2E are schematic views showing steps (ii) in one embodiment of the production method for a hollow structure. FIG. 2A is a diagram showing a step (ii-1).

FIG. 2B is a diagram showing a step (ii-2).

FIG. 2C1 is a diagram showing a step (ii-3).

FIG. 2C2 is a diagram showing a state after a step (ii-3).

FIG. 2D is a diagram showing a step (ii-4).

FIG. 2E is a diagram showing a step (ii-5).

FIG. 3 is a photograph of a height direction cross section of a negative pattern, and shows an evaluation standard in an evaluation of a negative pattern shape. In this photograph, a state on a left side is evaluation A, and a state on a right side is evaluation B.

FIG. 4 is a photograph of a line portion surface of a negative pattern, and shows an evaluation standard in an evaluation of a defect on a negative pattern surface. In this photograph, a left side is a surface roughened state (X) of the pattern, and a right side is a surface roughened state (Y) of the pattern.

### DESCRIPTION OF EMBODIMENTS

In the present specification and the claims, the term “aliphatic” is a relative concept used with respect to the term “aromatic” and defines a group with no aromaticity, a compound with no aromaticity, or the like.

A term “alkyl group” includes linear, branched, or cyclic monovalent saturated hydrocarbon groups unless otherwise specified. The same applies to an alkyl group in an alkoxy group.

A term “alkylene group” includes linear, branched, or cyclic divalent saturated hydrocarbon groups unless otherwise specified.

A “halogenated alkyl group” is a group in which a part of or all of hydrogen atoms in an alkyl group are substituted with halogen atoms. As the halogen atom, a fluorine atom, a chlorine atom, a bromine atom, and an iodine atom are exemplary examples.

A “fluorinated alkyl group” refers to a group in which a part of or all of hydrogen atoms in an alkyl group are substituted with fluorine atoms.

The term “constitutional unit” indicates a monomer unit constituting a polymer compound (a resin, a polymer, or a copolymer).

The expression “may have a substituent” includes a case where a hydrogen atom (—H) is substituted with a monovalent group and a case where a methylene group (—CH₂—) is substituted with a divalent group.

A term “exposure” is used as a general concept for irradiation with radiation.

### (Production Method for Hollow Structure)

A first aspect of the present invention relates to a production method for a hollow structure consisting of a concave portion that is surrounded by a substrate and a side wall formed on the substrate and a top plate portion that blocks an opening surface of the concave portion, the production method including a step of obtaining the concave portion in which the side wall is formed on the substrate (hereinafter, this step is referred to as “step (i)”) and a step of obtaining the hollow structure by forming the top plate portion on the side wall (hereinafter, this step is referred to as “step (ii)”).

In the production method for a hollow structure according to the first aspect, at least one of the side wall or the top plate portion is formed by using a laminate of a support and a resist layer.

When the at least one of the side wall or the top plate portion is formed by using the laminate, an operation of exposing the resist layer via the support and developing the laminate after the exposure with a developing solution containing an organic solvent to form a negative pattern is performed.

### <Laminate>

In the production method for a hollow structure according to the present aspect, a laminate of a specific support and a resist layer is used.

In one embodiment of the laminate, the support constituting the laminate consists of a polyethylene terephthalate film having a light transmittance of 85% or more at a wavelength of 365 nm and a haze value of 1.0% or less when irradiated with light having a wavelength of 365 nm.

In one embodiment of the laminate, the resist layer constituting the laminate consists of a photosensitive layer formed of a negative photosensitive composition.

### <<Support>>

The support constituting the laminate according to the present embodiment consists of a polyethylene terephthalate film.

In the present specification and the claims, an ultraviolet-visible-near infrared spectrophotometer is used in a light transmittance of the support, and a total light transmittance (%) in a wavelength range of 200 to 800 nm is measured, so that a light transmittance (%) at a wavelength of 360 nm is obtained.

In the support constituting the laminate according to the present embodiment, a light transmittance at a wavelength of 365 nm is 85% or more. The higher the light transmittance at a wavelength of 365 nm, the more preferable the light transmittance is.

In the present specification and the claims, the haze value of the support is measured by using a haze meter and by a method based on JIS K 7361-1, and the haze value (%) when irradiated with light having a wavelength of 365 nm is obtained.

In the support constituting the laminate according to the present embodiment, the haze value when irradiated with light having a wavelength of 365 nm is 1.0% or less, and is preferably 0.90% or less. The lower the haze value when irradiated with light having a wavelength of 365 nm is, the more preferable the haze value is.

In a case where the support consisting of a polyethylene terephthalate film has a light transmittance of 85% or more at a wavelength of 365 nm and a haze value when irradiated with light having a wavelength of 365 nm of 1.0% or less, an optical influence is suppressed, and lithography characteristics (shape and defect reduction) of a pattern is further improved.

A thickness of the support constituting the laminate according to the present embodiment is not particularly limited, and is, for example, in a range of 10 μm to 200 μm, and may be in a range of 20 μm to 100 μm.

### <<Resist Layer>>

The resist layer constituting the laminate according to the present embodiment consists of a photosensitive layer formed of a negative photosensitive composition.

Suitable examples of the negative photosensitive composition include a negative photosensitive composition containing an epoxy group-containing compound and a cationic polymerization initiator. Details of composition or the like of such a negative photosensitive composition will be described later.

A thickness of the resist layer constituting the laminate according to the present embodiment is not particularly limited, and is, for example, in a range of 1 μm to 100 μm, and may be in a range of 5 μm to 50 μm.

In the laminate of the present embodiment described above, since the specific support, that is, a polyethylene terephthalate film having a transmittance of 85% or more at a wavelength of 365 nm and a haze value of 1.0% or less when irradiated with light having a wavelength of 365 nm is provided, the optical influence is suppressed when the side wall or the top plate portion of the hollow structure is formed. As a result, it is possible to further improve the lithography characteristics (shape and defect reduction) of the pattern.

Such a laminate is suitable as a material for producing a hollow structure consisting of a concave portion that is surrounded by a substrate and a side wall formed on the substrate and a top plate portion that blocks an opening surface of the concave portion. That is, such a laminate is suitable as a material for producing a hollow structure consisting of a concave portion surrounded by a substrate and a side wall formed on the substrate and a top plate portion that blocks the opening surface of the concave portion.

Such a laminate may constitute a dry film resist by including a cover film on a surface of the resist layer opposite to the support.

As the cover film, a known film can be used, and for example, a polyethylene terephthalate film, a polyethylene film, a polypropylene film, or the like is used.

As the cover film, a film having an adhesive force with a photosensitive film smaller than that of a film of the support is preferable.

A thickness of the cover film is preferably 2 to 150 μm, more preferably 2 to 100 μm, and still more preferably 5 to 50 μm.

The film of the support and the cover film may be the same film materials or may be different film materials.

When the dry film resist is used, for example, the cover film can be peeled off, and the dry film resist can be used as the laminate of the support and the resist layer.

Hereinafter, one embodiment of the production method for a hollow structure will be described with reference to the drawings.

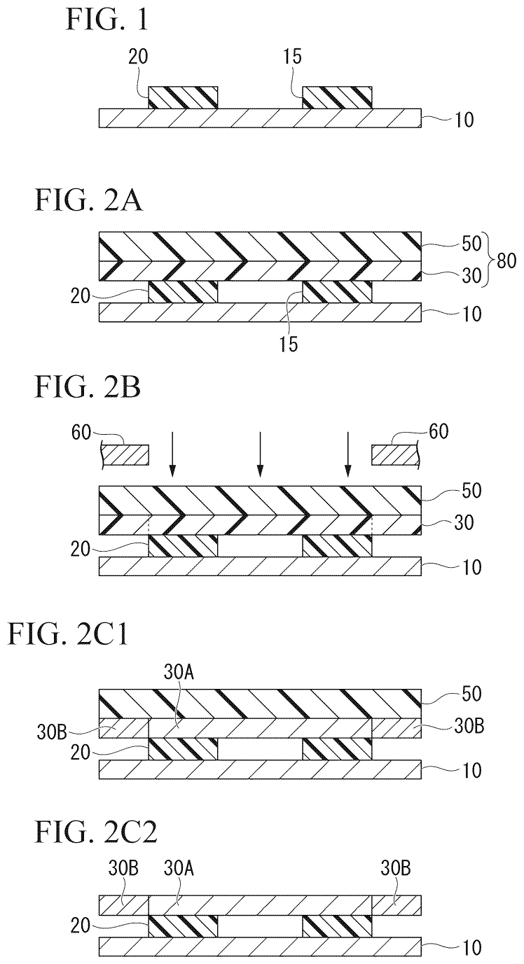

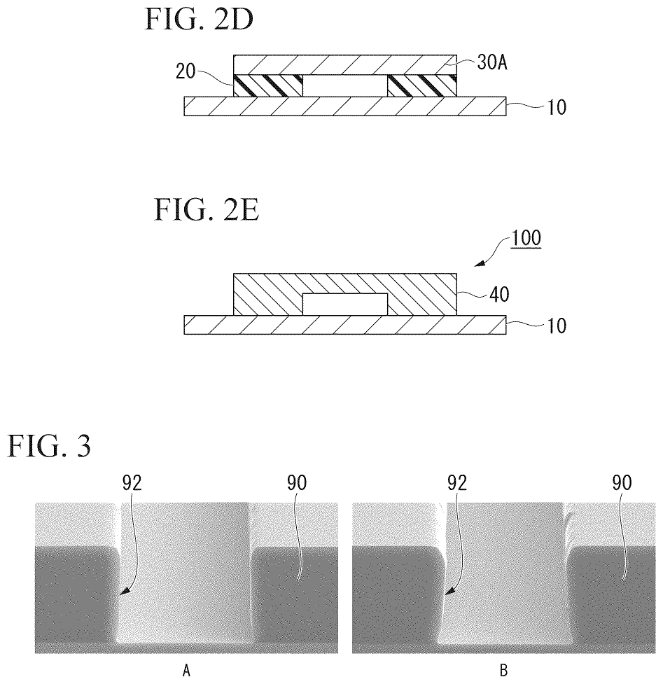

FIG. 1 is a schematic view showing the step (i), and shows an example of a substrate having a concave portion on a surface. FIGS. 2A to 2E are schematic views showing the step (ii).

[Step (i)]

In the step (i), the side wall is formed on the substrate, and the concave portion (the substrate having the concave portion on the surface) surrounded by the substrate and the side wall formed on the substrate is obtained.

Examples of the substrate having the concave portion on the surface include a structure in which a concave pattern is formed on the substrate, and a step substrate. The substrate having the concave portion on the surface can be produced by a method described below. Alternatively, a pre-manufactured product may be used as the substrate having the concave portion on the surface. The concave portion may be constituted of an organic material or may be constituted of an inorganic material.

In a case where the concave portion is constituted of an organic material, the substrate having the concave portion on the surface can be produced by a method including a step of forming a photosensitive film on a substrate using a negative photosensitive composition (hereinafter, referred to as “film forming step”), a step of exposing the photosensitive film (hereinafter, referred to as “exposing step”), and a step of developing the photosensitive film after the exposure with a developing solution containing an organic solvent to form a negative pattern serving as a side wall of the concave portion (hereinafter, referred to as “developing step”).

The method for producing the substrate having the concave portion on the surface as described above can be performed as follows.

### Film Forming Step:

First, a photosensitive film is formed by coating a substrate with the negative photosensitive composition using known methods such as a spin coating method, a roll coating method, and a screen printing method, and by performing a bake (post apply bake (PAB)) treatment under a temperature condition of, for example, 50° C. to 150° C. for 2 to 60 minutes.

The film forming step can also be performed by disposing a resist layer (a photosensitive layer) produced in advance on a substrate using a negative photosensitive composition. As laminating conditions at this time, for example, it is preferable that a temperature is set to 30° C. to 100° C., a pressure is set to 0.1 to 0.5 MPa, and a processing speed is set to 0.2 to 1.0 m/min.

The substrate is not particularly limited and a known substrate of the related art can be used, and examples thereof include a substrate for an electronic component or a substrate on which a predetermined wiring pattern has been formed.

Examples of the substrates for electronic components include, more specifically, substrates of metals such as silicon, silicon nitride, titanium, tantalum, lithium tantalate (LiTaO₃), niobium, lithium niobate (LiNbO₃), palladium, titanium tungsten, copper, chromium, iron, and aluminum, or glass substrates.

As the materials for the wiring pattern, for example, copper, aluminum, nickel, and gold can be used.

A film thickness of the photosensitive film formed of the negative photosensitive composition is not particularly limited, but is preferably approximately 1 to 100 μm.

### Exposing Step:

Next, the formed photosensitive film is exposed through a mask having a predetermined pattern (mask pattern) formed thereon using a known exposure device or selectively exposed through drawing or the like by performing direct irradiation with electron beams without using a mask pattern therebetween. Then, a bake (post-exposure bake (PEB)) treatment is performed as necessary under a temperature condition of, for example, 80° C. to 150° C. for 40 to 1200 seconds, preferably 40 to 1000 seconds and more preferably 60 to 900 seconds.

A wavelength used for the exposure is not particularly limited, the photosensitive film is selectively irradiated (exposed) with radiation, for example, ultraviolet rays having a wavelength of 300 to 500 nm, i-rays (wavelength: 365 nm), or visible light. As these radiation sources, a low pressure mercury lamp, a high pressure mercury lamp, an ultra-high pressure mercury lamp, a metal halide lamp, and an argon gas laser can be used.

Here, the radiation indicates ultraviolet rays, visible light rays, far ultraviolet rays, X-rays, electron beams, or the like. The irradiation amount of radiation varies depending on the kind of each component in the composition, the blending amount thereof, the film thickness of the coating film, and the like. For example, in a case where an ultra-high pressure mercury lamp is used, the irradiation amount thereof is in a range of 100 to 2000 mJ/cm².

The photosensitive film may be exposed through typical exposure (dry exposure) performed in air or an inert gas such as nitrogen or through liquid immersion exposure (liquid immersion lithography).

### Developing Step:

Next, the above-described photosensitive film after the exposure is developed with a developing solution (organic developing solution) containing an organic solvent. After the development, it is preferable that a rinse treatment is performed. As necessary, a baking treatment (post bake) may be performed.

The organic solvent contained in the organic developing solution can be appropriately selected from known organic solvents. Specifically, polar solvents such as ketone solvents, ester solvents, alcohol solvents, nitrile solvents, amide solvents, and ether solvents; and hydrocarbon solvents are exemplary examples.

As the ketone solvent, 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylenecarbonate, γ-butyrolactone, and methyl amyl ketone (2-heptanone) are exemplary examples. Among these, as the ketone solvent, methyl amyl ketone (2-heptanone) is preferable.

Examples of the ester solvents include methyl acetate, butyl acetate, ethyl acetate, isopropyl acetate, amyl acetate, isoamyl acetate, ethyl methoxyacetate, ethyl ethoxyacetate, propylene glycol monomethyl ether acetate (PGMEA), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetate, ethyl acetate, methyl propionate, ethyl propionate, propyl propionate, isopropyl propionate, methyl 2-hydroxypropionate, ethyl 2-hydroxypropionate, methyl 3-methoxypropionate, ethyl 3-methoxypropionate, ethyl 3-ethoxypropionate, and propyl 3-methoxypropionate. Among these, as the ester solvent, butyl acetate or PGMEA is preferable.

As the nitrile solvent, acetonitrile, propionitrile, valeronitrile, and butyronitrile are exemplary examples.

Known additives can be blended with the organic developing solution as necessary. As the additive, for example, a surfactant is an exemplary example. The surfactant is not particularly limited, and for example, an ionic or non-ionic fluorine-based and/or silicon-based surfactant can be used.

As the surfactant, a non-ionic surfactant is preferable, and a non-ionic fluorine-based surfactant or a non-ionic silicon-based surfactant is more preferable.

In a case where a surfactant is blended, the blending amount thereof is typically 0.001% to 5% by mass, preferably 0.005% to 2% by mass, and more preferably 0.01% to 0.5% by mass with respect to the total amount of the organic developing solution.

The development treatment can be performed by a known developing method. For example, a method of immersing a substrate in a developing solution for a predetermined time (a dip method), a method of stacking up a developing solution on the surface of a substrate using the surface tension and maintaining the state for a predetermined time (a puddle method), a method of spraying a developing solution to the surface of a substrate (a spray method), and a method of continuously ejecting a developing solution from a developing solution ejecting nozzle onto a substrate rotating at a constant speed while scanning the developing solution ejecting nozzle at a constant speed (a dynamic dispense method) are exemplary examples.

The rinse treatment (washing treatment) using a rinse liquid can be performed according to a known rinse method. Examples of a method of a rinsing treatment include a method in which a rinsing liquid is continuously applied onto a substrate rotating at a constant rate (a spin coating method), a method in which a substrate is immersed in a rinsing liquid for a certain period of time (a dipping method), and a method in which a rinsing liquid is sprayed onto a substrate surface (a spraying method).

In the rinse treatment, it is preferable to use a rinse liquid containing an organic solvent.

As shown in FIG. 1, by the film forming step, the exposing step, and the developing step in the above-described step (i), a side wall 20 is formed on a substrate 10, and a concave portion 15 surrounded by the substrate 10 and the side wall 20 formed on the substrate 10, that is, a substrate having the concave portion 15 on the surface can be produced. A shape of an upper surface of the side wall 20 is substantially rectangular in plan view from above.

A thickness (a dimension with respect to the substrate 10 in a horizontal direction) and a height (a dimension with respect to the substrate 10 in a vertical direction) of the side wall 20 can be appropriately set based on a size of a hollow portion, which is determined in accordance with a type of electronic device accommodated in the concave portion 15.

The negative photosensitive composition used in the step (i) to form the side wall 20 preferably contains an epoxy group-containing compound and a cationic polymerization initiator, and may be the same negative photosensitive composition as the photosensitive film constituting the top plate portion, which is used in the step (ii) described later.

In addition, in the step (i), in the film forming step, as the material for forming the side wall 20, a dry film resist in which a support, a resist layer, and a cover film are laminated in this order can also be used. In the dry film resist, it is preferable that the above-described laminate (the laminate of the support and the resist layer) is adopted in a laminated portion between the support and the resist layer.

In a case where the above-described laminate (the laminate of the support and the resist layer) is adopted, in the exposing step, the resist layer is exposed via the support without peeling off the support, a bake (post-exposure bake (PEB)) treatment is performed, and then an operation of developing the laminate with a developing solution containing an organic solvent to form a negative pattern is performed. By performing such an operation, it is possible to further improve the lithography characteristics of the pattern. In addition, a foreign matter can be prevented from being mixed into the resist layer, so that the hollow structure can be stably produced.

[Step (ii)]

In the step (ii), a top plate portion is formed on the side wall of the substrate having the concave portion on the surface, which is obtained in the step (i), to obtain a hollow structure.

As one embodiment of the step (ii), a case where the above-described laminate (the laminate of the support and the resist layer) is adopted is described, and examples thereof include a form in which the following steps (ii-1), (ii-2), (ii-3), (ii-4), and (ii-5) are performed in this order.

As a material for forming the top plate portion, the laminate (the laminate of the support and the resist layer) and the cover film on the resist layer are laminated to be used for the dry film resist. In FIG. 2A, the cover film has already been peeled off.

FIGS. 2A to 2E are schematic views showing the step (ii). The step (ii) is a form in which the following step (ii-1), step (ii-2), step (ii-3), step (ii-4), and step (ii-5) are performed in this order. FIGS. 2A to 2E are diagrams each showing the steps (ii-1) to (ii-5).

In FIGS. 2A to 2E, the substrate 10 and the side wall 20 formed on the substrate constitute a substrate having the concave portion 15 in the surface thereof. When the top plate portion is formed, a laminate 80 of a support 50 and a resist layer 30 is used.

[Step (ii-1)]

In the step (ii-1), the laminate 80 is disposed on an upper surface of the side wall such that a surface of the resist layer 30 of the laminate 80 blocks an opening surface of the concave portion 15 in the substrate 10 (FIG. 2A).

In lamination conditions when the laminate 80 is disposed on the upper surface of the side wall 20, for example, it is preferable that a temperature is set to 30° C. to 100° C., a pressure is set to 0.1 to 0.5 MPa, and a processing speed is set to 0.2 to 1.0 m/min.

In FIG. 2A, the laminate 80 is disposed to face the substrate 10 with the side wall 20 sandwiched therebetween. In addition, a hollow sealed space surrounded by the substrate 10, the side wall 20, and the resist layer 30 is formed.

[Step (ii-2)]

In the step (ii-2), the resist layer 30 is exposed via the support 50 (FIG. 2B).

As shown in FIG. 2B, for example, a selective exposure with respect to the resist layer 30 using a known exposure device via a photomask 60 on which a predetermined pattern is formed is performed by transmitting through the support 50.

The wavelength used for the exposure is not particularly limited, and radiation such as ultraviolet rays having a wavelength of 300 to 500 nm, i-line (wavelength of 365 nm), or visible rays selectively irradiated (exposed). As these radiation sources, a low pressure mercury lamp, a high pressure mercury lamp, an ultra-high pressure mercury lamp, a metal halide lamp, and an argon gas laser can be used.

[Step (ii-3)]

In the step (ii-3), a heat treatment, that is, a so-called post-exposure bake (PEB) treatment with respect to the resist layer 30 after the exposure is performed (FIG. 2C1). In this step (ii), the heat treatment in the step (ii-3) is performed at, for example, a temperature condition of 80° C. to 150° C. for 40 to 1200 seconds, preferably 40 to 1000 seconds and more preferably 60 to 900 seconds.

As shown in FIG. 2C1, by the PEB treatment in the step (ii-3), the resist layer 30 after the PEB treatment turns into an exposed portion 30A and an unexposed portion 30B that is not changed.

After the step (ii-3), the support 50 is peeled off from the resist layer 30 in the laminate 80 (FIG. 2C2).

[Step (ii-4)]

In the step (ii-4), the resist layer 30 (the exposed portion 30A and the unexposed portion 30B) after the PEB treatment is developed to form a negative pattern (the exposed portion 30A) (FIG. 2D),

The development here can be performed in the same manner as that of the developing step in the above-described step (i). After the development, it is preferable that a rinse treatment is performed.

[Step (ii-5)]

In the step (ii-5), a heat treatment with respect to the negative pattern (the exposed portion 30A) after the development is further performed to cure the negative pattern, thereby obtaining a hollow structure 100 in which the top plate portion consists of a cured body 40 of the resist layer 30 (FIG. 2E).

In FIG. 2E, in the cured body 40, a photosensitive material forming the side wall and the resist layer 30 are each cured to be integrated.

A temperature of the heat treatment in the step (ii-5) is, for example, 100° C. or higher, preferably 100° C. or higher and 250° C. or lower, and more preferably 150° C. or higher and 200° C. or lower.

A duration of the heat treatment in the step (ii-5) is, for example, 30 minutes or longer, preferably 30 minutes or longer and 120 minutes or shorter, and more preferably 30 minutes or longer and 90 minutes or shorter.

According to the production method for a hollow structure according to the embodiment, in which the step (i) and the step (ii) described above are provided, at least the top plate portion is formed by using the laminate of the specific support and the resist layer. When the top plate portion is formed, the laminate is used, and the exposure is performed via the specific support in a state in which the resist layer and the specific support are laminated, so that it is possible to suppress an optical influence and further improve the lithography characteristics (shape and defect reduction) of the pattern. In addition, when the top plate portion is formed, since the resist layer is in a laminated state with the specific support, deformation of the top plate portion due to thermal expansion of air in the hollow portion by the PEB treatment is suppressed, so that the hollow structure can be more stably produced.

The hollow structure produced by the production method including the step (i) and the step (ii) described above consists of the concave portion and a top plate portion that blocks the opening surface of the concave portion. The hollow structure can be suitably used for hollow packages used in SAW filters, MEMS, various sensors, or the like.

The production method for a hollow structure according to the above-described embodiment is useful for producing an insulating film for forming a semiconductor device.

In the production method including the step (i) and the step (ii) described above, the form has been described, in which both the side wall and the top plate portion or only the top plate portion is formed of the laminate of the support and the resist layer, but the present invention is not limited to thereto, and in the production method for a hollow structure according to the first aspect, a form in which only the side wall is formed of the laminate may be adopted. In any form, it is possible to suppress the optical influence and further improve the lithography characteristics of the pattern, and the hollow structure can be stably produced. In particular, when the top plate portion is formed, a form in which the laminate of the support and the resist layer is used is preferable because deformation of the top plate portion due to thermal expansion of air in the hollow portion by the PEB treatment is suppressed, so that the hollow structure can be more stably produced.

In addition, in the production method including the step (i) and the step (ii) described above, the form in which the support 50 is peeled off from the resist layer 30 in the laminate 80 after the PEB treatment in the step (ii-3) has been described, but the present invention is not limited thereto, and the production method for a hollow structure according to the first aspect, may be a form in which the support 50 is peeled off from the resist layer 30 in the laminate 80 after the exposure and before the PEB treatment. In this form, the air thermally expanded in the hollow portion by the PEB treatment can be easily discharged to the outside.

### Regarding Negative Photosensitive Composition:

The negative photosensitive composition (hereinafter, may be simply referred to as “photosensitive composition”) used in the present embodiment contains an epoxy group-containing compound (hereinafter, also referred to as “component (A)”) and a cationic polymerization initiator (hereinafter, also referred to as “component (I)”).

In a case where a photosensitive film is formed of such a photosensitive composition and selective exposure is performed on the photosensitive film, since a cation moiety of the component (I) is decomposed to generate an acid in an exposed portion of the photosensitive film, and an epoxy group in the component (A) is subjected to ring-opening polymerization due to an action of the acid so that solubility of the component (A) in an organic developing solution is decreased while the solubility of the component (A) in the developing solution containing an organic solvent is not changed in an unexposed portion of the photosensitive film. Therefore, a difference in solubility in the developing solution containing an organic solvent occurs between the exposed portion of the photosensitive film and the unexposed portion of the photosensitive film. Accordingly, in a case where the photosensitive film is developed with the developing solution containing an organic solvent, the unexposed portion is dissolved and removed so that a negative pattern is formed.

### <Epoxy Group-Containing Compound (A)>

In the photosensitive composition used in the present embodiment, examples of the epoxy group-containing compound (component (A)) include a compound having a sufficient epoxy group in one molecule to form a negative pattern by exposure.

Examples of the component (A) include a novolac-type epoxy resin (hereinafter, also referred to as “component (A1)”), a bisphenol-type epoxy resin (hereinafter, also referred to as “component (A2)”), an aliphatic epoxy resin, and an acrylic resin.

The component (A) may be used alone or may be used in combination of two or more kinds thereof.

However, the component (A) is defined as a component excluding components corresponding to a silane coupling agent.

### <<Novolak-Type Epoxy Resin>>

Suitable examples of the novolac type epoxy resin (hereinafter, also referred to as “component (A1)”) include an epoxy resin represented by General Formula (anv0).

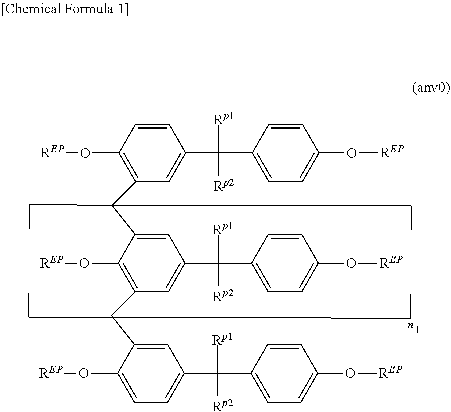

[In the Formula, R^{p1} and R^{p2} each independently represent a hydrogen atom or an alkyl group having 1 to 5 carbon atoms. A plurality of R^{p1}'s may be the same as or different from each other. A plurality of R²'s may be the same as or different from each other. n₁ represents an integer of 1 to 5. R^{EP} represents an epoxy group-containing group. A plurality of R^{EP}'s may be the same as or different from each other.]

In Formula (anv0), the alkyl group having 1 to 5 carbon atoms as R^{p1} and R^{p2} is, for example, a linear, branched, or cyclic alkyl group having 1 to 5 carbon atoms. As the linear or branched alkyl group, a methyl group, an ethyl group, a propyl group, an isopropyl group, an n-butyl group, an isobutyl group, a tert-butyl group, a pentyl group, an isopentyl group, and a neopentyl group are exemplary examples. As the cyclic alkyl group, a cyclobutyl group and a cyclopentyl group are exemplary examples.

Among these, R^{p1} and R^{p2} represent preferably a hydrogen atom or a linear or branched alkyl group, more preferably a hydrogen atom or a linear alkyl group, and particularly preferably a hydrogen atom or a methyl group.

In Formula (anv0), a plurality of R^{p1}'s may be the same as or different from each other. A plurality of R^{p2}'s may be the same as or different from each other.

In Formula (anv0), n₁ represents an integer of 1 to 5, preferably 2 or 3, and more preferably 2.

In Formula (anv0), R^{EP} represents an epoxy group-containing group.

The epoxy group-containing group as R^{EP} is not particularly limited, and examples thereof include a group consisting only of an epoxy group; a group consisting only of an alicyclic epoxy group; and a group having an epoxy group or an alicyclic epoxy group and a divalent linking group.

The alicyclic epoxy group is an alicyclic group having an oxacyclopropane structure as a 3-membered ring ether. Specifically, the alicyclic epoxy group is a group having an alicyclic group and an oxacyclopropane structure.

An alicyclic group which is a basic skeleton of the alicyclic epoxy group may be monocyclic or polycyclic. As the monocyclic alicyclic group, a cyclopropyl group, a cyclobutyl group, a cyclopentyl group, a cyclohexyl group, a cycloheptyl group, and a cyclooctyl group are exemplary examples. In addition, as the polycyclic alicyclic group, a norbornyl group, an isobornyl group, a tricyclononyl group, a tricyclodecyl group, and a tetracyclododecyl group are exemplary examples. In addition, hydrogen atoms in these alicyclic groups may be substituted with an alkyl group, an alkoxy group, a hydroxyl group, or the like.

In a case of the group having an epoxy group or an alicyclic epoxy group and a divalent linking group, it is preferable that the epoxy group or the alicyclic epoxy group is bonded through a divalent linking group bonded to an oxygen atom (—O—) in the Formula.

Here, the divalent linking group is not particularly limited, and a divalent hydrocarbon group which may have a substituent and a divalent linking group including a hetero atom are suitable exemplary examples.

Regarding the divalent hydrocarbon group which may have a substituent:
such a divalent hydrocarbon group may be an aliphatic hydrocarbon group or an aromatic hydrocarbon group; and
the aliphatic hydrocarbon group in the divalent hydrocarbon group may be saturated or unsaturated, and in general, it is preferable that the aliphatic hydrocarbon group is saturated.

More specifically, as the aliphatic hydrocarbon group, a linear or branched aliphatic hydrocarbon group and an aliphatic hydrocarbon group including a ring in the structure thereof are exemplary examples.

The number of carbon atoms in the above-described linear aliphatic hydrocarbon group is preferably 1 to 10, more preferably 1 to 6, still more preferably 1 to 4, and most preferably 1 to 3. As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The number of carbon atoms in the above-described branched aliphatic hydrocarbon group is preferably 2 to 10, more preferably 2 to 6, still more preferably 2 to 4, and most preferably 2 to 3. As the branched aliphatic hydrocarbon group, a branched alkylene group is preferable, and specific examples thereof include alkylalkylene groups, for example, alkylmethylene groups such as —CH(CH)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As an alkyl group in the alkylalkylene group, a linear alkyl group having 1 to 5 carbon atoms is preferable.

As the aliphatic hydrocarbon group including a ring in the structure thereof, an alicyclic hydrocarbon group (a group formed by removing two hydrogen atoms from an aliphatic hydrocarbon ring), a group in which an alicyclic hydrocarbon group is bonded to the terminal of a linear or branched aliphatic hydrocarbon group, and a group in which an alicyclic hydrocarbon group is interposed in a linear or branched aliphatic hydrocarbon group are exemplary examples. As the linear or branched aliphatic hydrocarbon group, the same as those described above is an exemplary example.

The number of carbon atoms in the alicyclic hydrocarbon group is preferably 3 to 20 and more preferably 3 to 12.

The alicyclic hydrocarbon group may be a polycyclic group or a monocyclic group. As the monocyclic alicyclic hydrocarbon group, a group formed by removing two hydrogen atoms from a monocycloalkane is preferable. The number of carbon atoms in the monocycloalkane is preferably 3 to 6, and specifically, cyclopentane and cyclohexane are exemplary examples.

As the polycyclic alicyclic hydrocarbon group, a group formed by removing two hydrogen atoms from a polycycloalkane is preferable. The number of carbon atoms in the polycycloalkane is preferably 7 to 12, and specifically, adamantane, norbornane, isobornane, tricyclodecane, and tetracyclododecane are exemplary examples.

The aromatic hydrocarbon group in the divalent hydrocarbon group has at least one aromatic ring. The aromatic ring is not particularly limited as long as the aromatic ring has a cyclic conjugated system having (4n+2) pieces of π electrons, and may be monocyclic or polycyclic. The number of carbon atoms in the aromatic ring is preferably 5 to 30, more preferably 5 to 20, still more preferably 6 to 15, and particularly preferably 6 to 12. Specifically, as the aromatic ring, an aromatic hydrocarbon ring such as benzene, naphthalene, anthracene, and phenanthrene; and an aromatic heterocyclic ring in which a part of carbon atoms constituting the above-described aromatic hydrocarbon ring are substituted with hetero atoms are exemplary examples. As the hetero atom in the aromatic heterocyclic ring, an oxygen atom, a sulfur atom, and a nitrogen atom are exemplary examples. Specifically, as the aromatic heterocyclic ring, a pyridine ring and a thiophene ring are exemplary examples.

Specifically, as the aromatic hydrocarbon group, a group (an arylene group or a heteroarylene group) formed by removing two hydrogen atoms from the aromatic hydrocarbon ring or the aromatic heterocyclic ring; a group formed by removing two hydrogen atoms from an aromatic compound (for example, biphenyl, fluorene, or the like) having two or more aromatic rings; and a group (for example, a group in which one hydrogen atom is further removed from an aryl group in an arylalkyl group such as a benzyl group, a phenethyl group, a 1-naphthylmethyl group, a 2-naphthylmethyl group, a 1-naphthylethyl group, and a 2-naphthylethyl group) in which one hydrogen atom of a group (an aryl group or a heteroaryl group) formed by removing one hydrogen atom from the aromatic hydrocarbon ring or the aromatic heterocyclic ring is substituted with an alkylene group are exemplary examples. The number of carbon atoms in the alkylene group which is bonded to the above-described aryl group or heteroaryl group is preferably 1 to 4, more preferably 1 or 2, and particularly preferably 1.

The divalent hydrocarbon group may have a substituent.

The linear or branched aliphatic hydrocarbon group as the divalent hydrocarbon group may or may not have a substituent. As the substituent, a fluorine atom, a fluorinated alkyl group having 1 to 5 carbon atoms which is substituted with a fluorine atom, and a carbonyl group are exemplary examples.

The alicyclic hydrocarbon group in the aliphatic hydrocarbon group including a ring in the structure thereof, as the divalent hydrocarbon group, may or may not have a substituent. As the substituent, an alkyl group, an alkoxy group, a halogen atom, a halogenated alkyl group, a hydroxyl group, and a carbonyl group are exemplary examples.

As the alkyl group as the above-described substituent, an alkyl group having 1 to 5 carbon atoms is preferable, and a methyl group, an ethyl group, a propyl group, an n-butyl group, or a tert-butyl group is most preferable.

As the alkoxy group as the above-described substituent, an alkoxy group having 1 to 5 carbon atoms is preferable, a methoxy group, an ethoxy group, an n-propoxy group, an iso-propoxy group, an n-butoxy group, or a tert-butoxy group is preferable, and a methoxy group or an ethoxy group is most preferable.

As the halogen atom as the above-described substituent, a fluorine atom, a chlorine atom, a bromine atom, and an iodine atom are exemplary examples. Among these, a fluorine atom is preferable.

As the halogenated alkyl group as the above-described substituent, a group in which a part of or all of hydrogen atoms in the alkyl group are substituted with the halogen atoms is an exemplary example.

In the alicyclic hydrocarbon group, a part of carbon atoms constituting the ring structure thereof may be substituted with substituents having a hetero atom. As the substituent having a heteroatom, —O—, —C(═O)—O—, —S—, —S(═O)₂—, or —S(═O)₂—O— is preferable.

In the aromatic hydrocarbon group as the divalent hydrocarbon group, a hydrogen atom in the aromatic hydrocarbon group may be substituted with a substituent. For example, the hydrogen atom bonded to the aromatic ring in the aromatic hydrocarbon group may be substituted with a substituent. As the substituent, an alkyl group, an alkoxy group, a halogen atom, a halogenated alkyl group, and a hydroxyl group are exemplary examples.

As the alkyl group as the above-described substituent, an alkyl group having 1 to 5 carbon atoms is preferable, and a methyl group, an ethyl group, a propyl group, an n-butyl group, or a tert-butyl group is most preferable.

As the alkoxy group, the halogen atom, and the halogenated alkyl group as the above-described substituent, the same as exemplary examples of the substituent which substitutes the hydrogen atom in the above-described alicyclic hydrocarbon group is an exemplary example.

Regarding divalent linking group including hetero atom:
the hetero atom in the divalent linking group including a hetero atom is an atom other than a carbon atom and a hydrogen atom, and an oxygen atom, a nitrogen atom, a sulfur atom, and a halogen atom are exemplary examples.

In the divalent linking group including a heteroatom, preferred examples of the linking group include —O—, —C(═O)—O—, —C(═O)—, —O—C(═O)—O—; —C(═O)—NH—, —NH—, —NH—C(═O)—O—, —NH—C(═NH)— (H may be substituted with a substituent such as an alkyl group, an acyl group, and the like); —S—, —S(═O)₂—, —S(═O)₂—O—, and a group represented by Formulae —Y²¹—O—Y²²—, —Y²¹—O—, —Y²¹—C(═O)—O—, —C(═O)—O—Y²¹, —[Y²¹—C(═O)—O]_{m″}—Y²—, or —Y²¹—O—C(═O)—Y²²— [in the Formulae, Y²t and Y²² each independently represent a divalent hydrocarbon group which may have a substituent, 0 represents an oxygen atom, and m″ represents an integer of 0 to 3].

In a case where the above-described divalent linking group including a hetero atom is —C(═O)—NH—, —NH—, —NH—C(═O)—O—, or —NH—C(═NH)—, H may be substituted with a substituent such as an alkyl group, an acyl, and the like. The substituent (alkyl group, acyl group, and the like) preferably has 1 to 10 carbon atoms, more preferably has 1 to 8 carbon atoms, and particularly preferably has I to 5 carbon atoms.

In Formulae —Y²¹—O—Y²²—, —Y²¹—O—, —Y²¹—C(═O)—O—, —C(═O)—O—Y²¹—, —[Y²¹—C(═O)—O]_{m″}—Y²²—, or —Y²¹—O—C(═O)—Y²²—, Y²¹ and Y²² each independently represent a divalent hydrocarbon group which may have a substituent. As the divalent hydrocarbon group, the same groups as those described above as the “divalent hydrocarbon group which may have a substituent” in the definition of the above-described divalent linking group are exemplary examples.

Y²¹ represents preferably a linear aliphatic hydrocarbon group, more preferably a linear alkylene group, still more preferably a linear alkylene group having 1 to 5 carbon atoms, and particularly preferably a methylene group or an ethylene group.

Y²² represents preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by General Formula —[Y²¹—C(═O)—O]˜_{m″}—Y²²—, m″ represents an integer in a range of 0 to 3, preferably an integer in a range of 0 to 2, more preferably 0 or 1, and particularly preferably 1. That is, a group represented by Formula —Y²¹—C(═O)—O—Y²²— is particularly preferable as the group represented by Formula —[Y^{Z1}—C(═O)—O]_{m″}—Y²²—. Among these, a group represented by Formula —(CH₂)_{a′}—C(═O)—O—(CH₂)_{b′}— is preferable. In the Formula, a′ represents an integer of I to 10, preferably an integer of I to 8, more preferably an integer of 1 to 5, still more preferably 1 or 2, and most preferably 1. b′ is an integer of 1 to 10, preferably an integer of 1 to 8, more preferably an integer of I to 5, still more preferably 1 or 2, and most preferably 1.

Among these, a glycidyl group is preferable as the epoxy group-containing group represented by R^{EP}.

In addition, as the component (A1), a resin having a constitutional unit represented by General Formula (anv1) is also a suitable exemplary example.

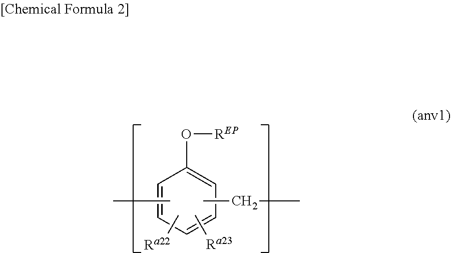

[In the Formula, R^{EP} represents an epoxy group-containing group. R^{a22} and R^{a23} each independently represent a hydrogen atom, an alkyl group having 1 to 5 carbon atoms, or a halogen atom.]

In Formula (anv1), the alkyl group having 1 to 5 carbon atoms as R^{a22} and R^{a23} has the same definition as that for the alkyl group having 1 to 5 carbon atoms as R^{p1} and R^{p2} in Formula (anv0).

It is preferable that the halogen atom as R^{a22} and R^{a23} is a chlorine atom or a bromine atom.

In Formula (any 1), R^{EP} has the same definition as that for R^{EP} in Formula (anv0), and it is preferable that R^{EP} represents a glycidyl group.

Specific examples of the constitutional unit represented by Formula (anv1) are shown below.

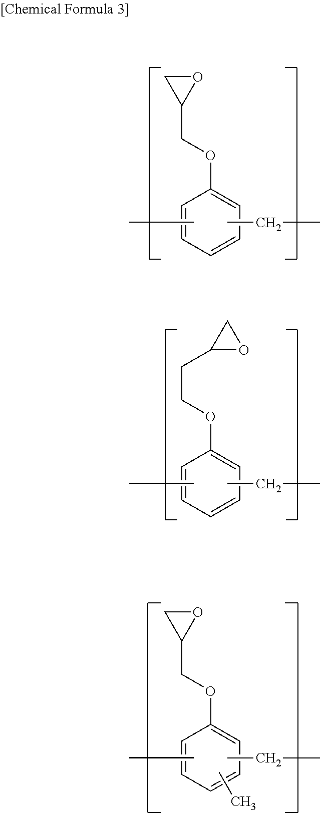

The component (A1) may be a resin consisting of only the above-described constitutional unit (anv1) or a resin having the constitutional unit (anv1) and other constitutional units.

As the other constitutional units, constitutional units represented by General Formulae (anv2) and (anv3) are exemplary examples.

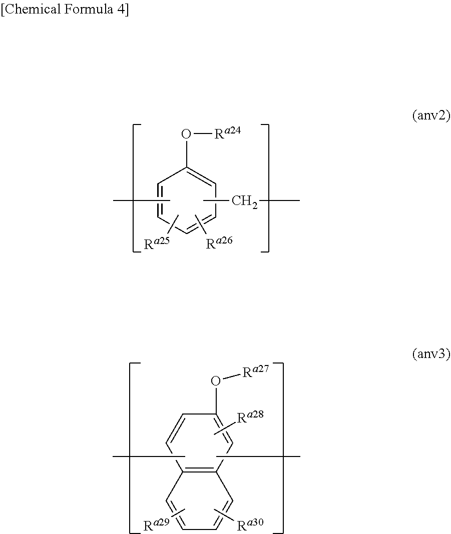

[In the Formulae, R^{a24} represents a hydrocarbon group which may have a substituent. R^{a25} and R^{a26}, and R^{a28} to R^{a30} each independently represent a hydrogen atom, an alkyl group having 1 to 5 carbon atoms, or a halogen atom. R^{a27} represents an epoxy group-containing group or a hydrocarbon group which may have a substituent.]

In Formula (anv2), R^{a24} represents a hydrocarbon group which may have a substituent. As the hydrocarbon group which may have a substituent, a linear or branched alkyl group and a cyclic hydrocarbon group are exemplary examples.

The linear alkyl group preferably has 1 to 5 carbon atoms, more preferably has 1 to 4 carbon atoms, and still more preferably has 1 or 2 carbon atoms. Specifically, a methyl group, an ethyl group, an n-propyl group, an n-butyl group, and an n-pentyl group are exemplary examples. Among these, a methyl group, an ethyl group, or an n-butyl group is preferable, and a methyl group or an ethyl group is more preferable.

The branched alkyl group preferably has 3 to 10 carbon atoms and more preferably has 3 to 5 carbon atoms. Specifically, an isopropyl group, an isobutyl group, a tert-butyl group, an isopentyl group, a neopentyl group, 1,1-diethylpropyl group, and a 2,2-dimethylbutyl group are exemplary examples. Among these, an isopropyl group is preferable.

In a case where R^{a24} represents a cyclic hydrocarbon group, the hydrocarbon group may be an aliphatic hydrocarbon group or an aromatic hydrocarbon group, and may be a polycyclic group or a monocyclic group.

As the aliphatic hydrocarbon group which is a monocyclic group, a group formed by removing one hydrogen atom from a monocycloalkane is preferable. The number of carbon atoms in the monocycloalkane is preferably 3 to 6, and specifically, cyclopentane and cyclohexane are exemplary examples.

As the aliphatic hydrocarbon group which is a polycyclic group, a group formed by removing one hydrogen atom from a polycycloalkane is preferable. The number of carbon atoms in the polycycloalkane is preferably 7 to 12, and specifically, adamantane, norbornane, isobornane, tricyclodecane, and tetracyclododecane are exemplary examples.

In a case where the cyclic hydrocarbon group as R^{a24} is an aromatic hydrocarbon group, the aromatic hydrocarbon group has at least one aromatic ring.

The aromatic ring is not particularly limited as long as the aromatic ring has a cyclic conjugated system having (4n+2) pieces of π electrons, and may be monocyclic or polycyclic. The number of carbon atoms in the aromatic ring is preferably 5 to 30, more preferably 5 to 20, still more preferably 6 to 15, and particularly preferably 6 to 12. Specifically, as the aromatic ring, an aromatic hydrocarbon ring such as benzene, naphthalene, anthracene, and phenanthrene; and an aromatic heterocyclic ring in which a part of carbon atoms constituting the above-described aromatic hydrocarbon ring are substituted with hetero atoms are exemplary examples. As the hetero atom in the aromatic heterocyclic ring, an oxygen atom, a sulfur atom, and a nitrogen atom are exemplary examples. Specifically, as the aromatic heterocyclic ring, a pyridine ring and a thiophene ring are exemplary examples.

Specific examples of the aromatic hydrocarbon group as R^{a24} include a group in which one hydrogen atom has been removed from the above-described aromatic hydrocarbon ring or aromatic heterocyclic ring (such as an aryl group or a heteroaryl group); a group in which one hydrogen atom has been removed from an aromatic compound having two or more aromatic rings (such as biphenyl or fluorene); and a group in which one hydrogen atom of the above-described aromatic hydrocarbon ring or aromatic heterocyclic ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The number of carbon atoms in the alkylene group which is bonded to the aromatic hydrocarbon ring or the aromatic heterocyclic ring is preferably 1 to 4, more preferably 1 or 2, and particularly preferably 1.

In Formulae (anv2) and (anv3), R^{a25} and R^{a26}, and R^{a28} to R^{a30} each independently represent a hydrogen atom, an alkyl group having 1 to 5 carbon atoms, or a halogen atom.

The alkyl group having 1 to 5 carbon atoms and the halogen atom each have the same definition as that for R^{a22} and R^{a23} described above.

In Formula (anv3), R^{a27} represents an epoxy group-containing group or a hydrocarbon group which may have a substituent. The epoxy group-containing group as R^{a27} has the same definition as that for R^{FP} in Formula (anv0) described above. The hydrocarbon group as R^{a27}, which may have a substituent, has the same definition as that for R^{a24} in Formula (anv2) described above.

Specific examples of the constitutional units represented by Formulae (anv2) and (anv3) are shown below.

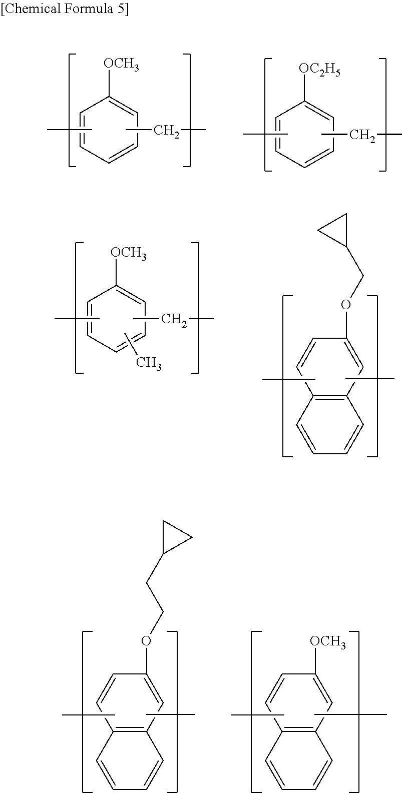

In a case where the component (A1) has other constitutional units in addition to the constitutional unit (any 1), a proportion of each constitutional unit in the component (A1) is not particularly limited, but the total amount of the constitutional units having an epoxy group is preferably 10% to 90% by mole, more preferably 20% to 80% by mole, and still more preferably 30% to 70% by mole with respect to the total amount of all constitutional units constituting the component (A1).

Examples of a commercially available product of the component (A1) include, as novolac type epoxy resins, jER-152, jER-154, jER-157S70, and jER-157S65 (all manufactured by Mitsubishi Chemical Corporation), EPICLON N-740, EPICLON N-740, EPICLON N-770, EPICLON N-775, EPICLON N-660, EPICLON N-665, EPICLON N-670, EPICLON N-673, EPICLON N-680, EPICLON N-690, EPICLON N-695, and EPICLON HP5000 (all manufactured by DIC Corporation), and EOCN-1020 (manufactured by Nippon Kayaku Co., Ltd.).

The component (A1) may be used alone or in combination of two or more kinds thereof.

In the photosensitive composition used in the present embodiment, a content of the component (A 1) is preferably 10 to 40 parts by mass, more preferably 15 to 35 parts by mass, and still more preferably 20 to 30 parts by mass in a case where the total mass of the component (A) is set to 100 parts by mass.

### <<Bisphenol-Type Epoxy Resin>>

The bisphenol-type epoxy resin (hereinafter, also referred to as “component (A2)”) may be any resin having a constitutional unit including a bisphenol skeleton, and among these, a solid bisphenol-type epoxy resin is preferable.

The solid bisphenol-type epoxy resin refers to a resin having a constitutional unit including a bisphenol skeleton, which is solid at 25° C.

An epoxy equivalent of the component (A2) is, for example, preferably 800 g/eq. or more, more preferably 800 to 1200 g/eq., and still more preferably 900 to 1100 g/eq.

As the component (A2), an epoxy resin represented by General Formula (abp1) is a suitable exemplary example.

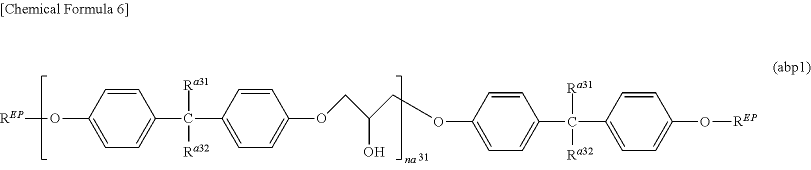

[In the Formula, R^{EP} represents an epoxy group-containing group. A plurality of R^{EP}'s may be the same as or different from each other. R^{a31} and R^{a12} each independently represent a hydrogen atom, an alkyl group having 1 to 5 carbon atoms, or a fluorinated alkyl group having 1 to 5 carbon atoms. na³¹ represents an integer of 1 to 50.]

In Formula (abp1), R^{EP} has the same definition as that for R^{EP} in Formula (anv0), and it is preferable that R^{EP} represents a glycidyl group.

In Formula (abp1), the alkyl group having 1 to 5 carbon atoms as R^{a31} and R^{a32} has the same definition as the alkyl group having 1 to 5 carbon atoms as R^{p1} and R^{p2} in Formula (anv0). Among these, it is preferable that R^{a31} and R^{a32} each represent a hydrogen atom or a methyl group.

Examples of the fluorinated alkyl group having 1 to 5 carbon atoms as R^{a31} and R^{a32} include a group in which some or all hydrogen atoms in the alkyl group having 1 to 5 carbon atoms as R^{a31} and R^{a32} described above have been substituted with fluorine atoms.

In Formula (abp1), na³¹ represents an integer of 1 to 50, preferably an integer of 4 to 15, and more preferably an integer of 5 to 8.

Examples of a commercially available product which can be used as the component (A2) include JER-4005, JER-4007, and JER-4010 (all manufactured by Mitsubishi Chemical Corporation); JER-827, JER-828, JER-834, JER-1001, JER-1002, JER-1003, JER-1055, JER-1007, JER-1009, and JER-1010 (all manufactured by Mitsubishi Chemical Corporation); and EPICLON 860, EPICLON 1050, EPICLON 1051, and EPICLON 1055 (all manufactured by DIC Corporation).

The component (A2) may be used alone or in combination of two or more kinds thereof.

In the photosensitive composition used in the present embodiment, the content of the component (A2) is preferably 60 to 90 parts by mass, more preferably 65 to 85 parts by mass, and still more preferably 70 to 80 parts by mass in a case where the total mass of the components (A) is set to 100 parts by mass.

In a case where the component (A1) and the component (A2) are used in combination, a ratio of the component (A1) and the component (A2) is preferably 1/9 or more and 5/5 or less, more preferably 1/9 or more and less than 5/5, still more preferably 2/8 or more and 4/6 or less, and particularly preferably 2/8 or more and 3/7 or less, as a mass ratio represented by the component (A 1)/component (A2).

In a case where such a mass ratio is within the above-described preferred range, a resolution is further improved, and a pattern (a side wall) having high adhesiveness with a wiring layer is easily formed.

### <<Aliphatic Epoxy Resin>>

As the aliphatic epoxy resin, for example, a compound represented by General Formula (ta1) (hereinafter, this compound is also referred to as “component (A3)”) is a suitable exemplary example.

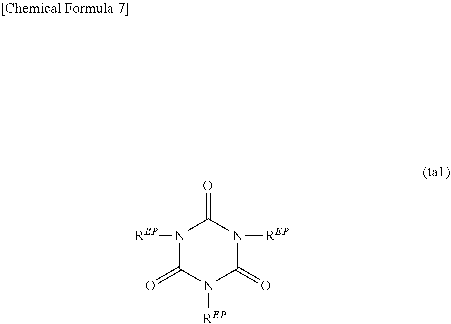

[In the Formula, R^{EP} represents an epoxy group-containing group. A plurality of R^{EP}'s may be the same as or different from each other.]

In Formula (ta1), R^{EP} represents an epoxy group-containing group, and has the same definition as that for R^{EP} in Formula (anv0).

As a commercially available product which can be used as the component (A3), for example, TEPIC series such as TEPTC, TEPIC-VL, TEPIC-PAS, TEPIC-G, TEPIC-S, TEPTC-SP, TEPTC-SS, TEPIC-HP, TEPIC-L., TEPIC-FL, and TEPIC-UC (manufactured by Nissan Chemical Industries, Ltd.); and MA-DGIC, DA-MGIC, and TOIC (manufactured by SHIKOKU KASEI HOLDINGS CORPORATION) are exemplary examples.

The component (A3) may be used alone or in combination of two or more kinds thereof.

In the photosensitive composition used in the present embodiment, a content of the component (A3) is preferably 0.1 to 10 parts by mass, more preferably 0.5 to 5 parts by mass, and still more preferably 1 to 3.5 parts by mass in a case where the total mass of the components (A) is set to 100 parts by mass.

In addition, as the aliphatic epoxy resin, a compound (hereinafter, also referred to as “component (m1)”) having a partial structure represented by General Formula (m1) is also an exemplary example.

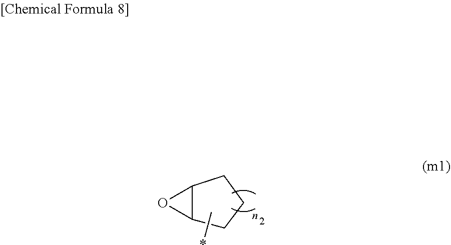

[In the Formula, n₂ represents an integer of 1 to 4. * represents a bonding site]

In Formula (m I), n₂ represents an integer of 1 to 4, preferably an integer of I to 3, and more preferably 2.

As the component (m1), compounds in which a plurality of the partial structures represented by General Formula (m1) described above are bonded through a divalent linking group or a single bond are exemplary examples. Among these, a compound in which a plurality of the partial structures represented by General Formula (m1) are bonded through a divalent linking group is preferable.

Here, the divalent linking group is not particularly limited, and a divalent hydrocarbon group which may have a substituent and a divalent linking group including a hetero atom is a suitable exemplary example.

Here, the divalent hydrocarbon group which may have a substituent and the divalent linking group including a hetero atom are the same as the divalent hydrocarbon group which may have a substituent and the divalent linking group including a hetero atom, described in R^{EP} (epoxy group-containing group) in the above-described Formula (anv0). Among these, the divalent linking group including a hetero atom is preferable, and a group represented by —Y^{Z1}—C(═O)—O— or a group represented by —C(═O)—O—Y²¹— is more preferable. Y²¹ represents preferably a linear aliphatic hydrocarbon group, more preferably a linear alkylene group, still more preferably a linear alkylene group having 1 to 5 carbon atoms, and particularly preferably a methylene group or an ethylene group.

As a commercially available product which can be used as the aliphatic epoxy resin, for example, ADEKA RESIN EP-4080S, ADEKA RESIN EP-4085S, and ADEKA RESIN EP-4088S (all manufactured by ADEKA CORPORATION); CELLOXIDE 2021P, CELLOXIDE 2081, CELLOXIDE 2083, CELLOXIDE 2085, CELLOXIDE 8000, CELLOXIDE 8010, EHPE-3150, EPOLEAD PB 3600, and EPOLEAD PB4700 (all manufactured by Daicel Corporation); and DENACOL EX-211L, EX-212L, EX-214L, EX-216L, EX-321 L, and EX-850L (all manufactured by Nagase ChemteX Corporation) are exemplary examples.

### Acrylic Resin

As the acrylic resin, for example, a resin having an epoxy group-containing unit represented by General Formula (a1-1) or (a1-2) is an exemplary example.

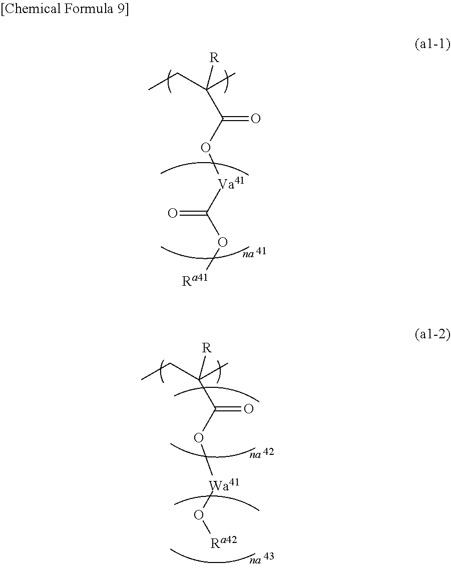

[in the Formulae, R is a hydrogen atom, an alkyl group having 1 to 5 carbon atoms, or a halogenated alkyl group having 1 to 5 carbon atoms, Va⁴¹ represents a divalent hydrocarbon group which may have a substituent. na⁴¹ represents an integer of 0 to 2. R^{a41} and R^{a42} each represent an epoxy group-containing group. na⁴² represents 0 or 1. Wa⁴¹ represents a (na⁴³+1)-valent aliphatic hydrocarbon group. na⁴³ represents an integer of 1 to 3.]

As the alkyl group having 1 to 5 carbon atoms as R in Formula (a1-1), a linear or branched alkyl group is preferable, and specifically, a methyl group, an ethyl group, a propyl group, an isopropyl group, an n-butyl group, an isobutyl group, a tert-butyl group, a pentyl group, an isopentyl group, and a neopentyl group are exemplary examples.

The halogenated alkyl group having 1 to 5 carbon atoms as R is a group in which a par of or all of hydrogen atoms in the alkyl group having 1 to 5 carbon atoms are substituted with halogen atoms. As the halogen atom, a fluorine atom, a chlorine atom, a bromine atom, and an iodine atom are exemplary examples. Among these, a fluorine atom is particularly preferable.

As R, a hydrogen atom, an alkyl group having 1 to 5 carbon atoms, or a fluorinated alkyl group having 1 to 5 carbon atoms is preferable, and a hydrogen atom or a methyl group is more preferable from the viewpoint of industrial availability.

In Formula (a1-1), Va⁴¹ is a divalent hydrocarbon group which may have a substituent, and the same groups as those for the divalent hydrocarbon group which may have a substituent, described in the section of R^{EP} in Formula (anv0), are exemplary examples.

Among these, as the hydrocarbon group represented by Va⁴¹, an aliphatic hydrocarbon group is preferable, a linear or branched aliphatic hydrocarbon group is more preferable, a linear aliphatic hydrocarbon group is still more preferable, and a linear alkylene group is particularly preferable.

In Formula (a1-1), na⁴¹ represents an integer of 0 to 2 and preferably 0 or 1.

In Formulae (a1-1) and (a1-2), R^{a41} and R^{a42} represent an epoxy group-containing group, and are the same as R^{EP} in Formula (anv0).

In Formula (a1-2), the (na⁴³+1)-valent aliphatic hydrocarbon group as Wa⁴¹ denotes a hydrocarbon group with no aromaticity, and may be saturated or unsaturated. In general, it is preferable that the aliphatic hydrocarbon group is saturated. As the above-described aliphatic hydrocarbon group, a linear or branched aliphatic hydrocarbon group, an aliphatic hydrocarbon group having a ring in the structure thereof, and a group formed by combining a linear or branched aliphatic hydrocarbon group and an aliphatic hydrocarbon group having a ring in the structure thereof are exemplary examples.

In Formula (a1-2), na⁴³ represents an integer of 1 to 3 and preferably 1 or 2.

Specific examples of the constitutional unit represented by Formula (a1-1) or (a1-2) are shown below.

In the following Formulae, R^{α} represents a hydrogen atom, a methyl group, or a trifluoromethyl group.

R^{a51} represents a divalent hydrocarbon group having 1 to 8 carbon atoms. R^{a52} represents a divalent hydrocarbon group having 1 to 20 carbon atoms. R^{a53} represents a hydrogen atom or a methyl group. na⁵¹ represents an integer of 0 to 10.

R^{a51}, R^{a52}, and R^{a53} may be the same as or different from each other.

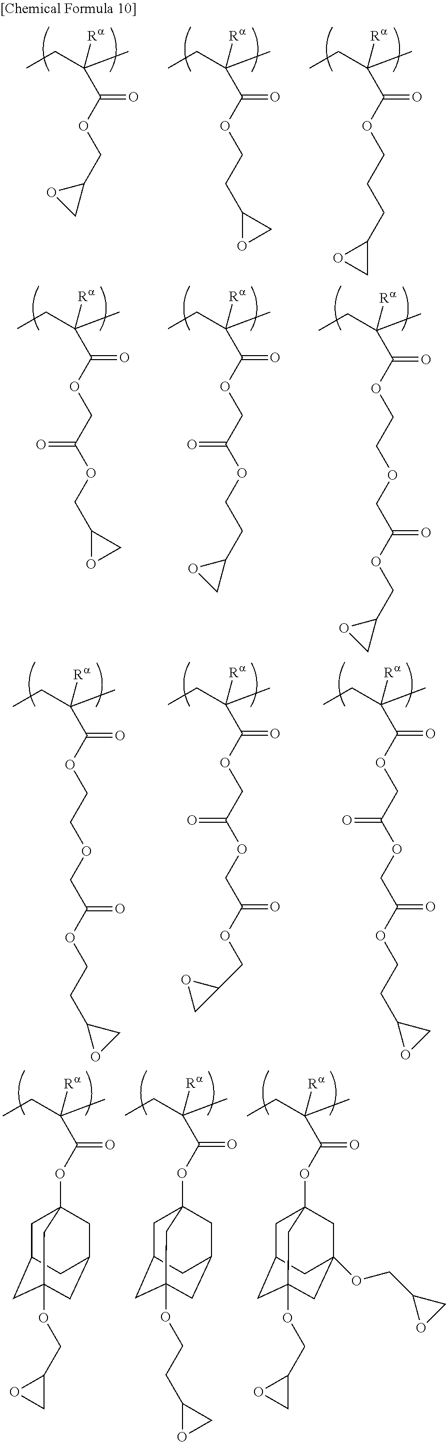

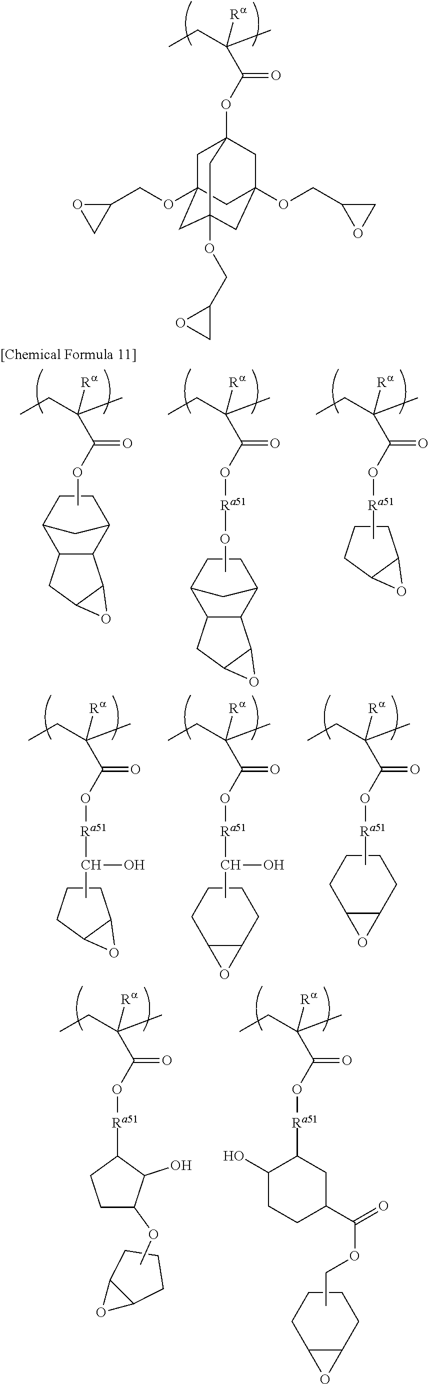

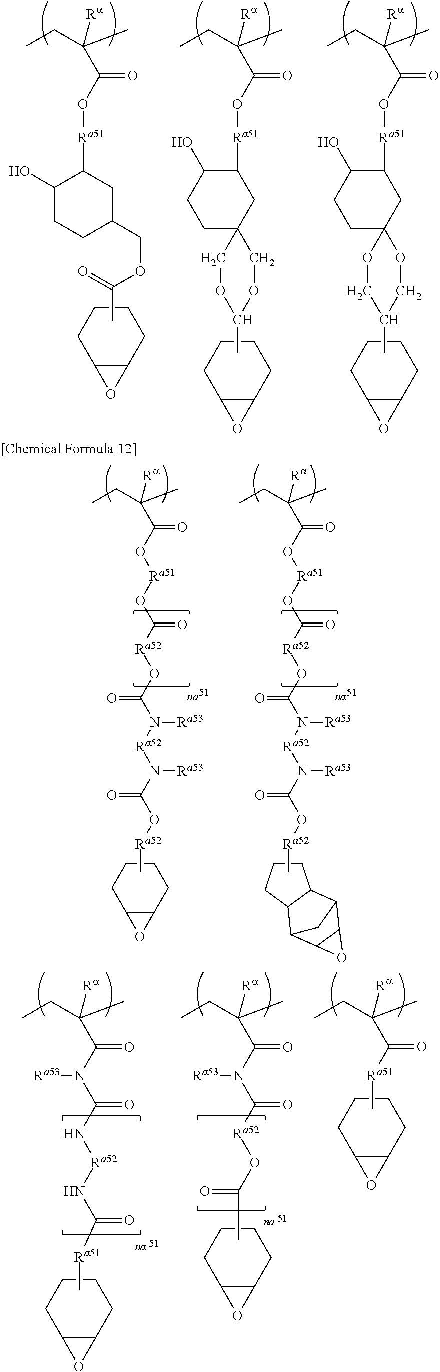

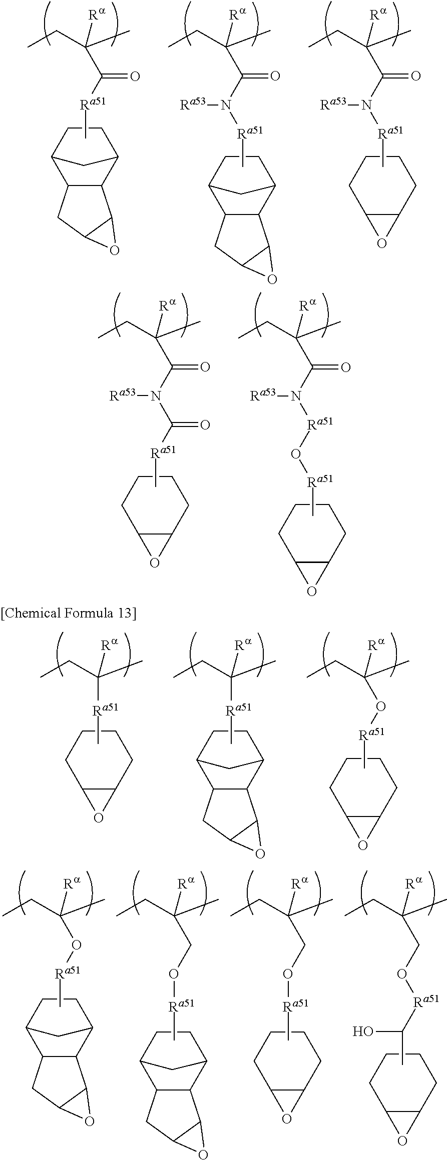

Further, the acrylic resin may have a constitutional unit derived from other polymerizable compounds for the purpose of appropriately controlling physical and chemical characteristics.

Examples of such a polymerizable compound include known radical polymerizable compounds or anionic polymerizable compounds. As such a polymerizable compound, monocarboxylic acids such as acrylic acid, methacrylic acid, and crotonic acid: dicarboxylic acids such as maleic acid, fumaric acid, and itaconic acid; methacrylic acid derivatives containing a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl (meth)acrylate, ethyl (meth)acrylate, and butyl (meth)acrylate; (meth)acrylic acid hydroxy alkyl esters such as 2-hydroxyethyl (meth)acrylate and 2-hydroxypropyl (meth)acrylate: (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene, and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide are exemplary examples.

In a case where the above-described acrylic resin has other constitutional units, a content ratio of the epoxy group-containing unit in the resin is preferably 5% to 40% by mole, more preferably 10% to 30% by mole, and still more preferably 15% to 25% by mole.

Further, as the epoxy group-containing compound, each of a compound represented by Chemical Formula (A4-1) and a compound represented by Chemical Formula (A4-2) may be used in addition to the above-described resins.

Examples of a commercially available product that can be used as the compound represented by Chemical Formula (A4-1) include TECHMORE VG-3101L (manufactured by Printec, Inc.).

Examples of a commercially available product that can be used as the compound represented by Chemical Formula (A4-2) include SHOFREE (registered trademark) BATG (manufactured by Showa Denko K.K.).

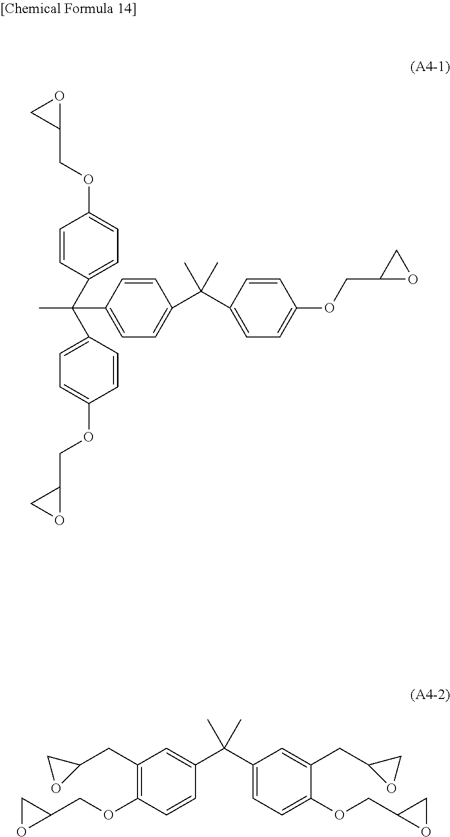 [SMILES: CC(C)(c1ccc(OCC2CO2)cc1)c1ccc(C(C)(c2ccc(OCC3CO3)cc2)c2ccc(OCC3CO3)cc2)cc1 ; CC(C)(c1ccc(OCC2CO2)c(CC2CO2)c1)c1ccc(OCC2CO2)c(CC2CO2)c1]

Further, examples of the epoxy group-containing compound include trimethylolpropane triglycidyl ether and glycerin triglycidyl ether, pentaerythritol tetraglycidyl ether, ditrimethylolpropane tetraglycidyl ether, diglycerin tetraglycidyl ether, and erythritol tetraglycidyl ether; xylitol pentaglycidyl ether, dipentaerythritol pentaglycidyl ether, and inositol pentaglycidyl ether; and dipentaerythritol hexaglycidyl ether, sorbitol hexaglycidyl ether, and inositol hexaglycidyl ether.

In the photosensitive composition used in the present embodiment, as the component (A), a component including the component (A 1) and the component (A2) is preferable, and among these, a component including the component (A1) and a solid bisphenol type epoxy resin is more preferable, and a component including an epoxy resin represented by General Formula (anv0) and an epoxy resin represented by General Formula (abp1) is still more preferable.

A mass-average molecular weight of the component (A) in terms of polystyrene is preferably 100 to 300,000, more preferably 200 to 200,000, and still more preferably 300 to 200,000. By setting the mass-average molecular weight as described above, it is difficult to occur peeling from the support (a substrate having a wiring layer or the like), and a hardness of the cured film to be formed is sufficiently increased.

A content of the component (A) in the photosensitive composition used in the embodiment may be adjusted in accordance with a film thickness of the photosensitive film to be formed.

### <Cationic Polymerization Initiator (I)>

In the photosensitive composition used in the present embodiment, the cationic polymerization initiator (component (I)) is a compound which generates a cation by receiving irradiation with actinic rays such as ultraviolet rays, far ultraviolet rays, an excimer laser beam such as KrF and ArF, X-rays, electron beams, or the like, and the cation may be a polymerization initiator.

Examples of the component (I) include onium borate salts (hereinafter, also referred to as “component (I1)”) and cationic polymerization initiators other than the component (I1) (other cationic polymerization initiators).

### <<Onium Borate Salt>>

The onium borate salt (component (I1)) generates a relatively strong acid upon light exposure. Therefore, by forming a pattern using the photosensitive composition containing the component (I1), sufficient sensitivity can be obtained and a favorable pattern can be formed. In addition, the use of the component (I1) has a low risk of toxicity or metal corrosion.

As the component (I1), for example, a compound represented by General Formula (I1) is a suitable exemplary example.

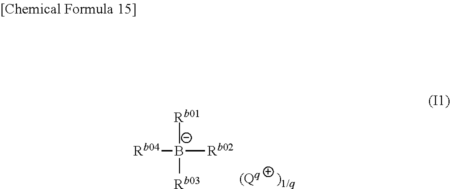

[In the Formula, R^{b01} to R^{b04} each independently represent an aryl group which may have a substituent or a fluorine atom. q represents an integer of 1 or greater, and Q^{q+} represents a q-valent organic cation.]

### Anion Moiety

In Formula (I1), the aryl group as R^{b01} to R^{b04} has preferably 5 to 30 carbon atoms, more preferably 5 to 20 carbon atoms, still more preferably 6 to 15 carbon atoms, and particularly preferably 6 to 12 carbon atoms. Specific examples thereof include a naphthyl group, a phenyl group, and an anthracenyl group. Among these, a phenyl group is preferable from the viewpoint of availability.

The aryl group as R^{b01} to R^{b04} may have a substituent. The substituent is not particularly limited. As the substituent, a halogen atom, a hydroxyl group, an alkyl group (preferably a linear or branched alkyl group having 1 to 5 carbon atoms), or a halogenated alkyl group is preferable, a halogen atom or a halogenated alkyl group having 1 to 5 carbon atoms is more preferable, and a fluorine atom or a fluorinated alkyl group having 1 to 5 carbon atoms is particularly preferable. It is preferable that the aryl group has a fluorine atom because the polarity of the anion moiety is increased.

Among these, R^{b01} to R^{b04} in Formula (I1) each represent preferably a fluorinated phenyl group and particularly preferably a perfluorophenyl group.

Specific preferred exemplary examples of the anion moiety of the compound represented by Formula (I1) are tetrakis(pentafluorophenyl)borate ([B(C₆F₅)₄]⁻); tetrakis[(trifluoromethyl)phenyl]borate ([B(C₆H₄CF₃)₄]⁻); difluorobis(pentafluorophenyl)borate ([(C₆F₅)₂BF₂]⁻); trifluoro(pentafluorophenyl)borate ([(C₆F₅)BF₃]⁻); and tetrakis(difluorophenyl)borate ([B(C₆H₃F₂)₄]⁻).

Among these, tetrakis(pentafluorophenyl)borate ([B(C₆F₅)₄]⁻) is particularly preferable.

### Cation Moiety

In Formula (I1), suitable examples of Q^{q+} include a sulfonium cation and an iodonium cation, and organic cations each represented by General Formulae (ca-1) to (ca-5) are particularly preferable.

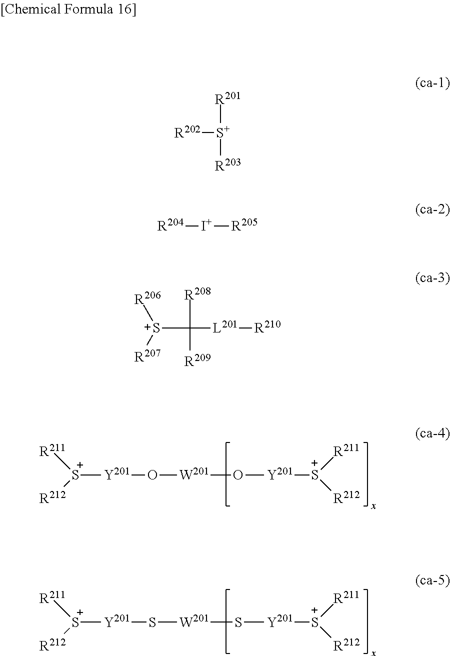

[In the Formulae, R²⁰¹ to R²⁰⁷, R²¹¹, and R²¹² each independently represent an aryl group, a heteroaryl group, an alkyl group, or an alkenyl group, which may have a substituent. R²⁰¹ to R²⁰³, R²⁰⁶ and R²⁰⁷, and R²¹¹ and R²¹² may be bonded to each other to form a ring with the sulfur atom in the Formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂-containing cyclic group which may have a substituent. L²⁰¹ represents —C(═O)— or —C(═O)—O—, Y²⁰¹'s each independently represent an arylene group, an alkylene group, or an alkenylene group. x is 1 or 2, and W²⁰¹ represents an (x+1)-valent linking group.]

Examples of the aryl group as R²⁰¹ to R²⁰⁷, R²¹¹, and R²¹² include an unsubstituted aryl group having 6 to 20 carbon atoms. Among the examples, a phenyl group or a naphthyl group is preferable.

Examples of the heteroaryl group as R²⁰¹ to R²⁰⁷, R²¹¹, and R²¹² include those obtained by substituting some carbon atoms constituting the aryl group with heteroatoms. As the hetero atom, an oxygen atom, a sulfur atom, and a nitrogen atom are exemplary examples. As the heteroaryl group, a group formed by removing one hydrogen atom from 9H-thioxanthene is an exemplary example, and as the substituted heteroaryl group, a group formed by removing one hydrogen atom from 9H-thioxanthene-9-one is an exemplary example.

The alkyl group as R²⁰¹ to R²⁰⁷, R²¹¹, and R²¹² is a chain-like or cyclic alkyl group, and the number of carbon atoms thereof is preferably in a range of 1 to 30.

It is preferable that the alkenyl group as R²⁰¹ to R²⁰⁷, R²¹¹, and R²¹² has 2 to 10 carbon atoms.

Examples of the substituent which may be contained in R²⁰¹ to R²⁰⁷ and R²¹⁰ to R²¹² include an alkyl group, a halogen atom, a halogenated alkyl group, a carbonyl group, a cyano group, an amino group, an oxo group (═O), an aryl group, and a group represented by any of General Formulae (ca-r-1) to (ca-r-10).

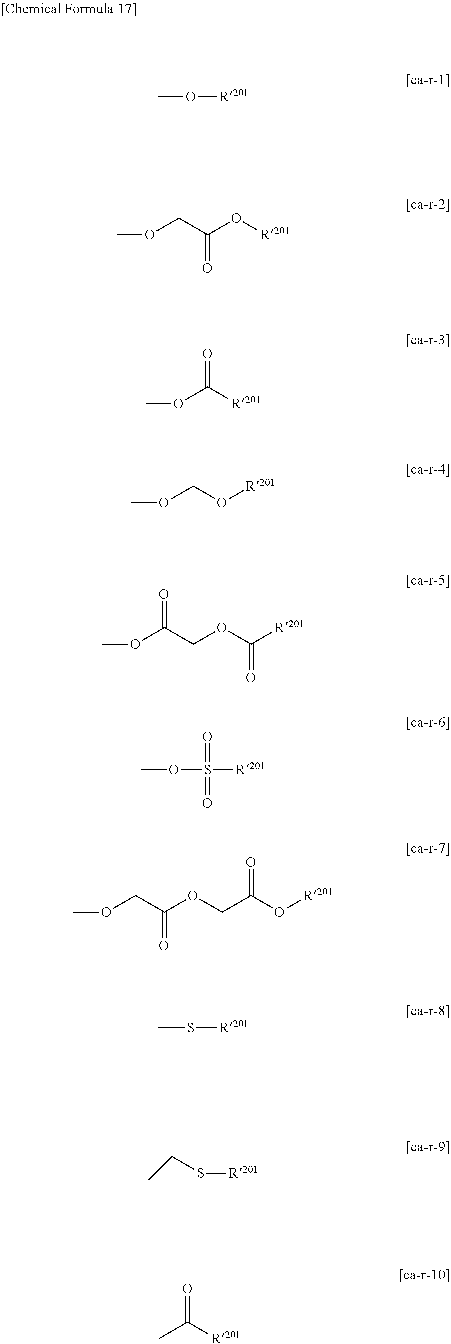

[In the Formulae, R′²⁰¹'s each independently represent a hydrogen atom, a cyclic group which may have a substituent, a chain-like alkyl group which may have a substituent, or a chain-like alkenyl group which may have a substituent.]

In Formulae (ca-r-1) to (ca-r-10), R′²⁰¹'s each independently represent a hydrogen atom, a cyclic group which may have a substituent, a chain-like alkyl group which may have a substituent, or a chain-like alkenyl group which may have a substituent.

Cyclic group which may have substituent:
it is preferable that the cyclic group is a cyclic hydrocarbon group, and the cyclic hydrocarbon group may be an aromatic hydrocarbon group or a cyclic aliphatic hydrocarbon group. The aliphatic hydrocarbon group indicates a hydrocarbon group with no aromaticity. In addition, the aliphatic hydrocarbon group may be saturated or unsaturated. In general, it is preferable that the aliphatic hydrocarbon group is saturated.

The aromatic hydrocarbon group as R′²⁰¹ has an aromatic ring. The number of carbon atoms in the aromatic hydrocarbon group is preferably 3 to 30, more preferably 5 to 30, still more preferably 5 to 20, particularly preferably 6 to 15, and most preferably 6 to 10. Here, the number of carbon atoms does not include the number of carbon atoms in a substituent.

Specific examples of the aromatic ring of the aromatic hydrocarbon group as R′²⁰¹ include benzene, fluorene, naphthalene, anthracene, phenanthrene, biphenyl, an aromatic heterocyclic ring in which some carbon atoms constituting these aromatic rings have been substituted with heteroatoms, and a ring in which some hydrogen atoms constituting these aromatic rings or aromatic heterocyclic rings have been substituted with oxo groups. As the hetero atom in the aromatic heterocyclic ring, an oxygen atom, a sulfur atom, and a nitrogen atom are exemplary examples.

Specific examples of the aromatic hydrocarbon group as R′²⁰¹ include a group obtained by removing one hydrogen atom from the aromatic ring (an aryl group such as a phenyl group, a naphthyl group, or an anthracenyl group), a group in which one hydrogen atom of the aromatic ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group), a group obtained by removing one hydrogen atom from a ring (such as anthraquinone) in which some hydrogen atoms constituting the aromatic ring have been substituted with an oxo group, and a group obtained by removing one hydrogen atom from an aromatic heterocyclic ring (such as 9H-thioxanthene or 9H-thioxanthene-9-one). The number of carbon atoms in the above-described alkylene group (an alkyl chain in the arylalkyl group) is preferably 1 to 4, more preferably 1 or 2, and particularly preferably 1.

Examples of the cyclic aliphatic hydrocarbon group as R′²⁰¹ include an aliphatic hydrocarbon group having a ring in the structure thereof.

Examples of the aliphatic hydrocarbon group having a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in the middle of a linear or branched aliphatic hydrocarbon group.

The number of carbon atoms in the alicyclic hydrocarbon group is preferably 3 to 20 and more preferably 3 to 12.

The alicyclic hydrocarbon group may be a polycyclic group or a monocyclic group. As the monocyclic alicyclic hydrocarbon group, a group formed by removing one or more hydrogen atoms from a monocycloalkane is preferable. The number of carbon atoms in the monocycloalkane is preferably 3 to 6, and specifically, cyclopentane and cyclohexane are exemplary examples. As the polycyclic alicyclic hydrocarbon group, a group formed by removing one or more hydrogen atoms from a polycycloalkane is preferable, and the number of carbon atoms in the polycycloalkane is preferably 7 to 30. Among these, a polycycloalkane having a bridged ring polycyclic skeleton, such as adamantane, norbornane, isobornane, tricyclodecane, and tetracyclododecane; or a polycycloalkane having a fused ring polycyclic skeleton, such as a cyclic group having a steroid skeleton, is more preferable.

Among these examples, as the cyclic aliphatic hydrocarbon group as R′²⁰¹, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is particularly preferable, and an adamantyl group is most preferable.

The number of carbon atoms in the linear or branched aliphatic hydrocarbon group which may be bonded to the alicyclic hydrocarbon group is preferably 1 to 10. more preferably 1 to 6, still more preferably 1 to 4, and most preferably 1 to 3.

As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂- and —CH₂CH(CH₃)CH₂—; and alkyltetramethylene groups such as —CH(CH₃)CH₂CH₂CH₂— and —CH₂CH(CH₃)CH₂CH₂—. As an alkyl group in the alkylalkylene group, a linear alkyl group having 1 to 5 carbon atoms is preferable.

Chain-like alkyl group which may have substituent:

The chain-like alkyl group as R′²⁰¹ may be linear or branched.

The number of carbon atoms in the linear alkyl group is preferably 1 to 20, more preferably 1 to 15, and most preferably 1 to 10. Specifically, a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group are exemplary examples.

The number of carbon atoms in the branched alkyl group is preferably 3 to 20, more preferably 3 to 15, and most preferably 3 to 10. Specifically, a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group are exemplary examples.

Chain-like alkenyl group which may have substituent:

The chain-like alkenyl group as R′²⁰¹ may be linear or branched, and the number of carbon atoms thereof is preferably in a range of 2 to 10, more preferably in a range of 2 to 5, still more preferably in a range of 2 to 4, and particularly preferably 3. As the linear alkenyl group, a vinyl group, a propenyl group (an allyl group), and a butynyl group are exemplary examples. As the branched alkenyl group, a 1-methylvinyl group, a 2-methylvinyl group, a I-methylpropenyl group, and a 2-methylpropenyl group are exemplary examples.

Among the above, as the chain-like alkenyl group, a linear alkenyl group is preferable, a vinyl group or a propenyl group is more preferable, and a vinyl group is particularly preferable.

Examples of the substituent for the cyclic group, the chain-like alkyl group, or the chain-like alkenyl group as R′²⁰¹ include an alkoxy group, a halogen atom, a halogenated alkyl group, a hydroxyl group, a carbonyl group, a nitro group, an amino group, an oxo group, the cyclic group as R′²⁰¹, an alkylcarbonyl group, and a thienylcarbonyl group.

Among these, it is preferable that R′²⁰¹ represents a cyclic group which may have a substituent or a chin-like alkyl group which may have a substituent.

In a case where R²⁰¹ to R²⁰³, R²⁰⁶ and R²⁰⁷, and R²¹¹ and R²¹² are bonded to each other to form a ring with a sulfur atom in the Formulae, these groups may be bonded to each other via a heteroatom such as a sulfur atom, an oxygen atom, or a nitrogen atom, or a functional group such as a carbonyl group, —SO—, —SO₂—, —SO₃—, —COO—, —CONH—, or —N(R_{N})— (R_{N} represents an alkyl group having 1 to 5 carbon atoms). As a ring to be formed, one ring containing the sulfur atom in the Formula in the ring skeleton thereof is preferably a 3- to 10-membered ring and particularly preferably a 5- to 7-membered ring, including the sulfur atom. Specific exemplary examples of the ring to be formed are a thiophene ring, a thiazole ring, a benzothiophene ring, a thianthrene ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

In Formula (ca-3), R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ represent an alkyl group, R²⁰⁸ and R²⁰⁹ may be bonded to each other to form a ring.

In Formula (ca-3), R²¹⁰ represents an aryl group which may have a substituent, an alkyl group which may have a substituent, an alkenyl group which may have a substituent, or a —SO₂-containing cyclic group which may have a substituent.

Examples of the aryl group as R²¹⁰ include an unsubstituted aryl group having 6 to 20 carbon atoms. Among these, a phenyl group or a naphthyl group is preferable.

As the alkyl group as R²¹⁰, a chain-like or cyclic alkyl group having 1 to 30 carbon atoms is preferable.

It is preferable that the alkenyl group as R²¹⁰ has 2 to 10 carbon atoms.

In Formula (ca-4) and Formula (ca-5), Y²⁰¹'s each independently represent an arylene group, an alkylene group, or an alkenylene group.

Examples of the arylene group as Y²⁰¹ include groups obtained by removing one hydrogen atom from the aryl groups described as the aromatic hydrocarbon group as R′²⁰¹.

Examples of the alkylene group and alkenylene group as Y²⁰¹ include groups obtained by removing one hydrogen atom from the groups described as the chain-like alkyl group and the chain-like alkenyl group as R′²⁰¹.

In Formulae (ca-4) and (ca-5), x is 1 or 2.

W²⁰¹ represents an (x+1)-valent linking group, that is, a divalent or trivalent linking group.

As the divalent linking group in W²⁰¹, a divalent hydrocarbon group which may have a substituent is preferable. Further, the same divalent hydrocarbon groups which may have a substituent as exemplary examples in the section of R^{EP} in the above-described Formula (A1) described above are preferable. The divalent linking group as W²⁰¹ may be either linear, branched, or cyclic, and is preferably cyclic. Among these, a group formed by combining two carbonyl groups at both ends of an arylene group or a group consisting of only an arylene group is preferable. As the arylene group, a phenylene group and a naphthylene group are exemplary examples. Among these, a phenylene group is particularly preferable.

Examples of the trivalent linking group as W²⁰¹ include a group in which one hydrogen atom has been removed from the above-described divalent linking group as W²⁰¹ and a group obtained by bonding the divalent linking group to another divalent linking group described above. As the trivalent linking group as W²⁰¹, a group obtained by bonding two carbonyl groups to an arylene group is preferable.

As the cation represented by Formula (ca-1), specifically, cations represented by Formulae (ca-1-1) to (ca-1-24) are suitable exemplary examples.

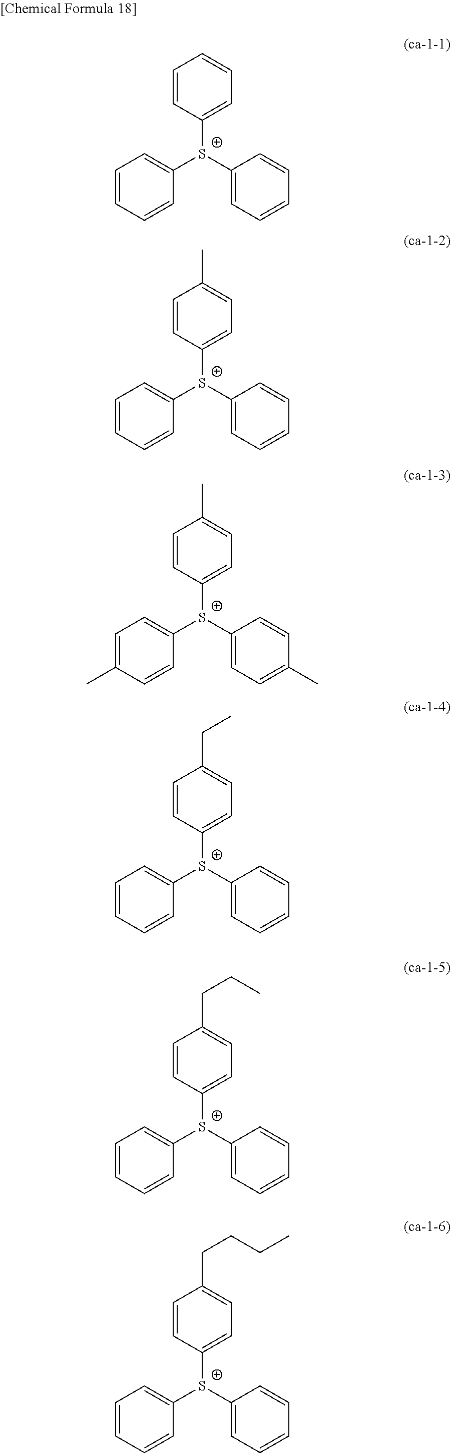

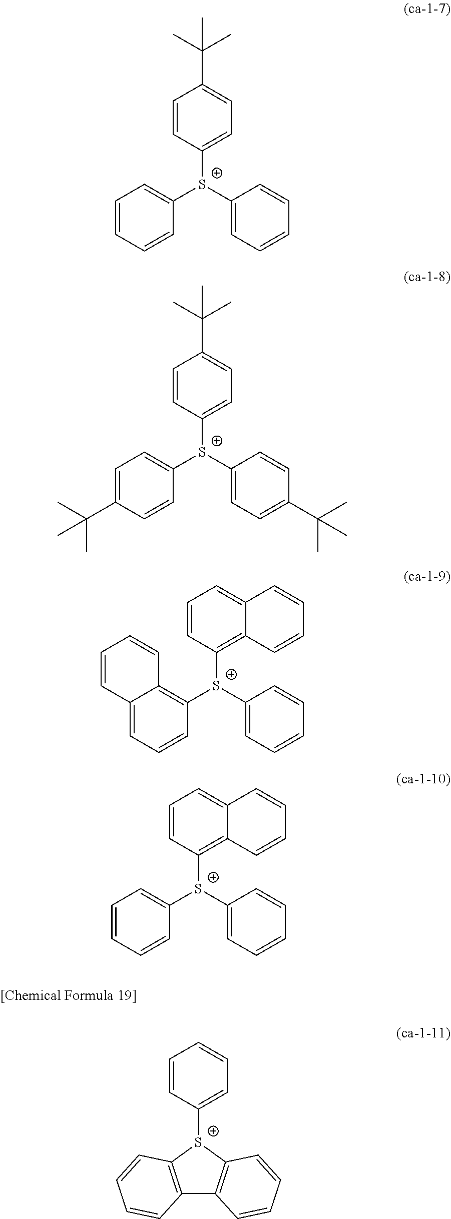 [SMILES: CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; c1ccc([S+](c2cccc3ccccc23)c2cccc3ccccc23)cc1 ; c1ccc([S+](c2ccccc2)c2cccc3ccccc23)cc1 ; c1ccc(-[s+]2c3ccccc3c3ccccc32)cc1]

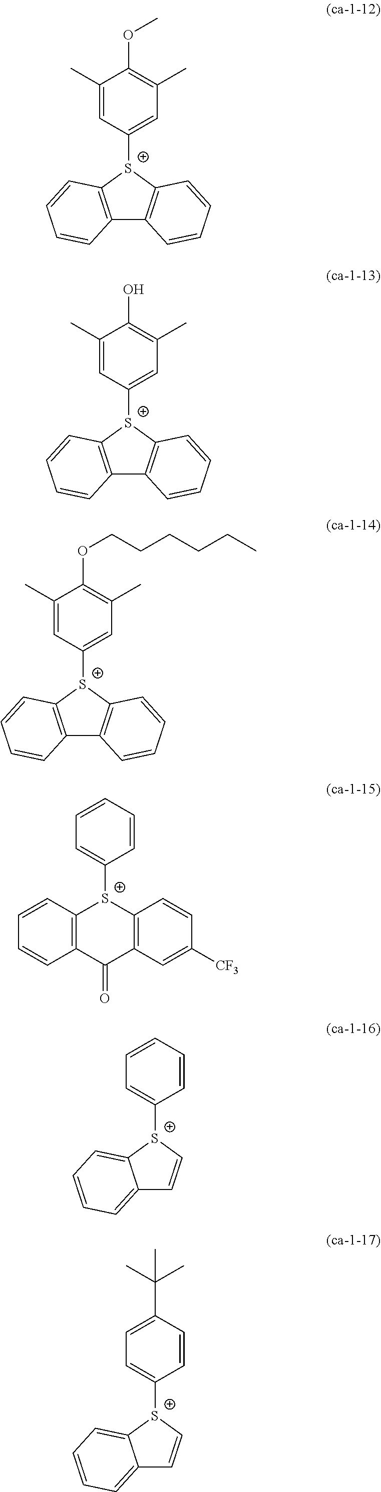 [SMILES: COc1c(C)cc(-[s+]2c3ccccc3c3ccccc32)cc1C ; Cc1cc(-[s+]2c3ccccc3c3ccccc32)cc(C)c1O ; CCCCCCOc1c(C)cc(-[s+]2c3ccccc3c3ccccc32)cc1C ; O=c1c2ccccc2[s+](-c2ccccc2)c2ccc(C(F)(F)F)cc12 ; c1ccc(-[s+]2ccc3ccccc32)cc1 ; CC(C)(C)c1ccc(-[s+]2ccc3ccccc32)cc1]

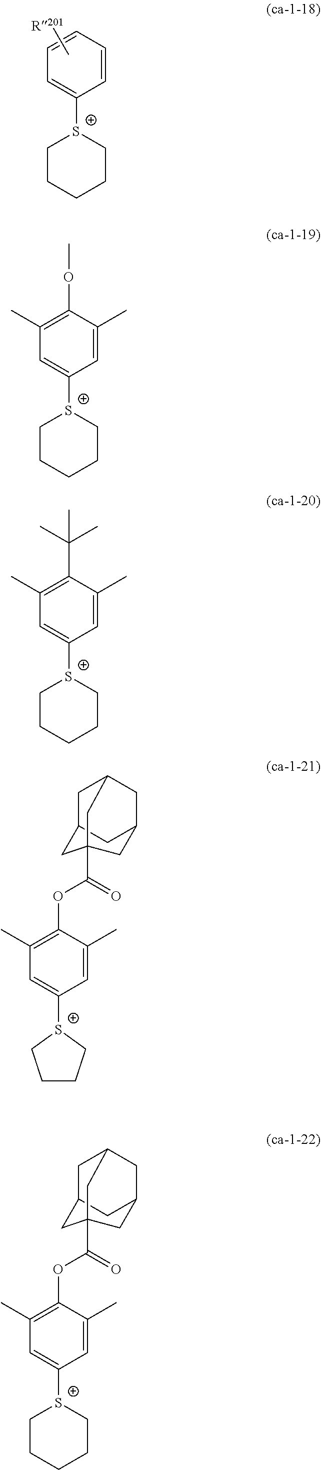

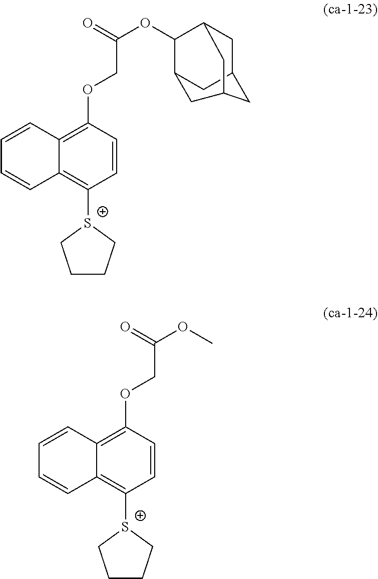 [SMILES: O=C(COc1ccc([S+]2CCCC2)c2ccccc12)OC1C2CC3CC(C2)CC1C3 ; COC(=O)COc1ccc([S+]2CCCC2)c2ccccc12]

[In the Formulae. R″²⁰¹ represents a hydrogen atom or a substituent. Examples of the substituent include the same groups as the substituents which may be included in R²⁰¹ to R²⁰⁷ and R²¹⁰ to R²¹².

In addition, as the cation represented by Formula (ca-1), cations represented by General Formulae (ca-1-25) to (ca-1-35) are also preferable.

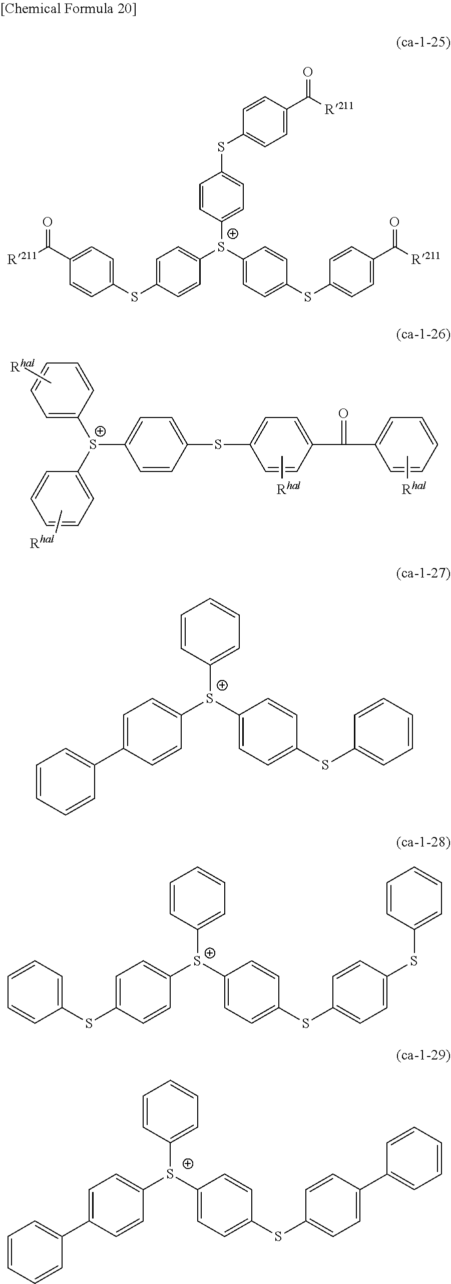

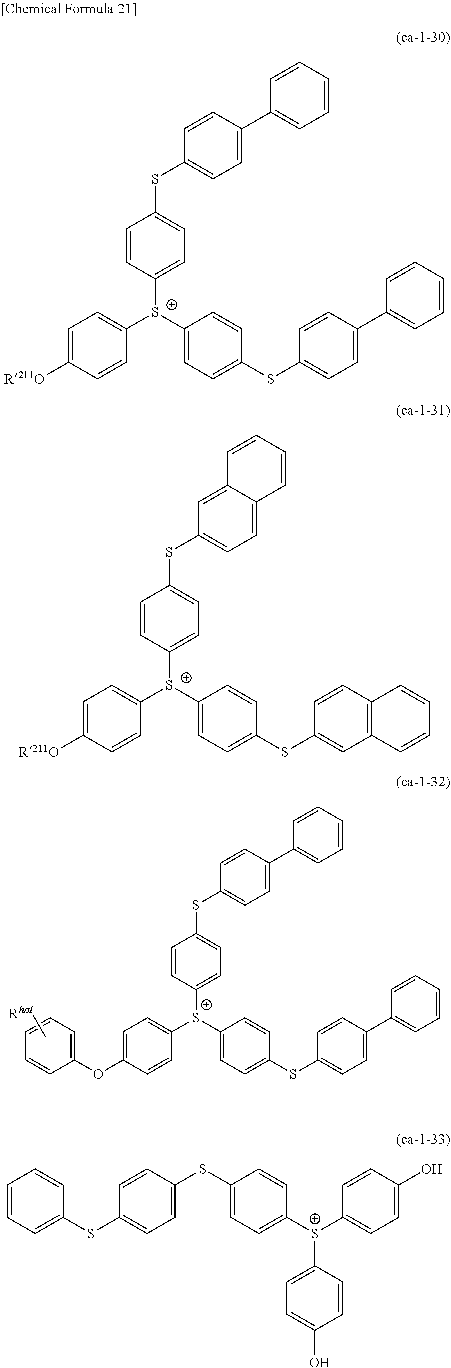

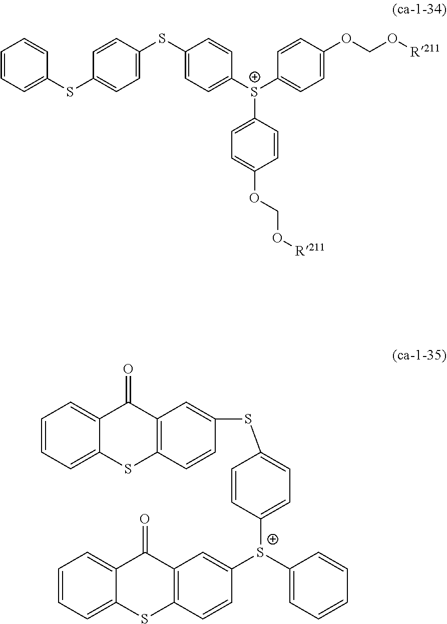

In the Formulae, R′²¹¹ represents an alkyl group. R^{hal} represents a hydrogen atom or a halogen atom.]

In addition, as the cation represented by Formula (ca-1), cations represented by Chemical Formulae (ca-1-36) to (ca-I-48) are also preferable.

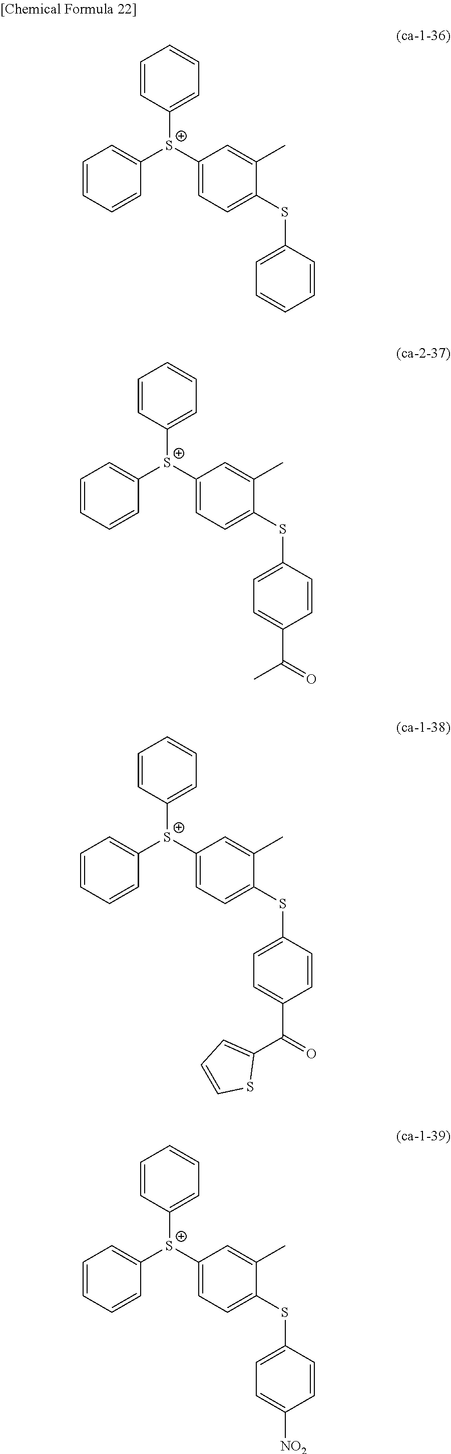

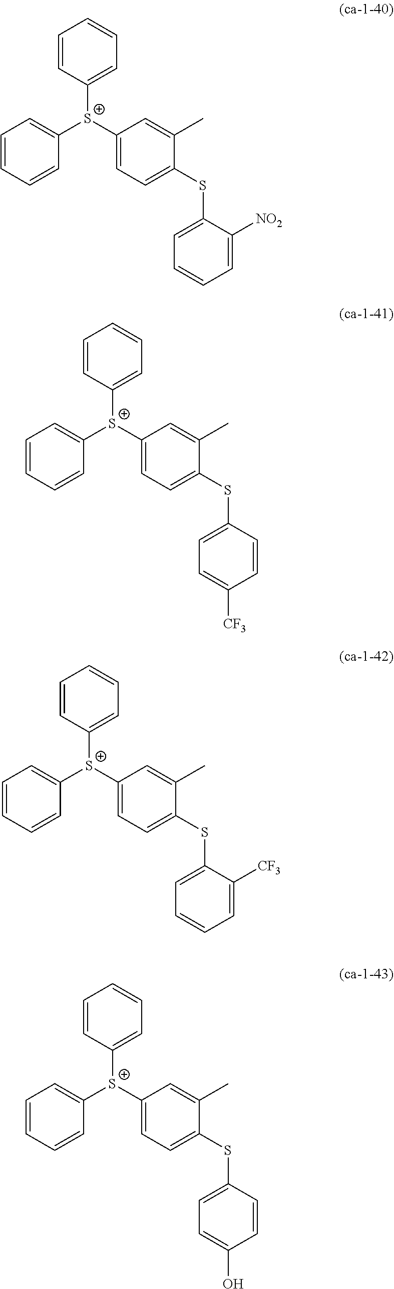 [SMILES: Cc1cc([S+](c2ccccc2)c2ccccc2)ccc1Sc1ccccc1[N+](=O)[O-] ; Cc1cc([S+](c2ccccc2)c2ccccc2)ccc1Sc1ccc(C(F)(F)F)cc1 ; Cc1cc([S+](c2ccccc2)c2ccccc2)ccc1Sc1ccccc1C(F)(F)F ; Cc1cc([S+](c2ccccc2)c2ccccc2)ccc1Sc1ccc(O)cc1]

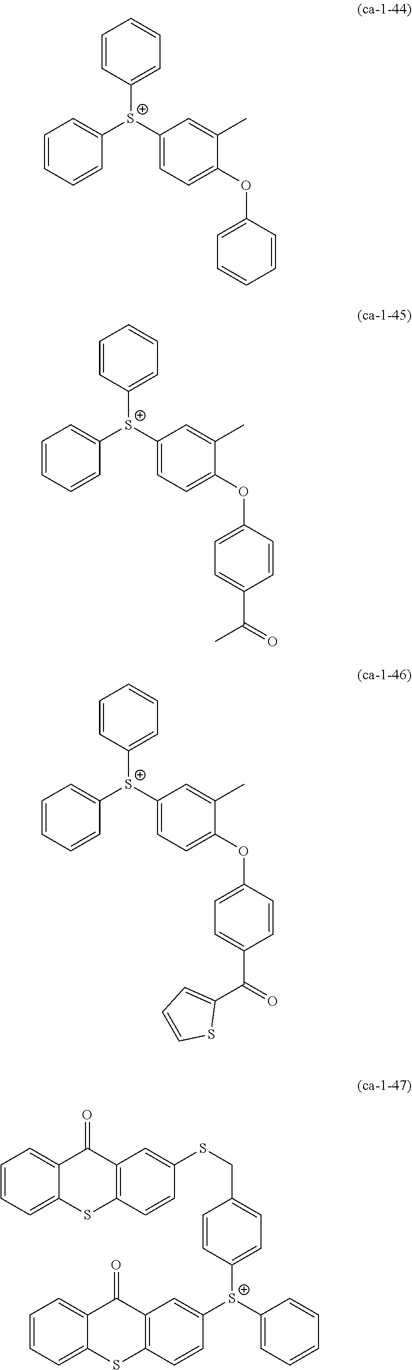 [SMILES: Cc1cc([S+](c2ccccc2)c2ccccc2)ccc1Oc1ccccc1 ; CC(=O)c1ccc(Oc2ccc([S+](c3ccccc3)c3ccccc3)cc2C)cc1 ; Cc1cc([S+](c2ccccc2)c2ccccc2)ccc1Oc1ccc(C(=O)c2cccs2)cc1 ; O=c1c2ccccc2sc2ccc(SCc3ccc([S+](c4ccccc4)c4ccc5sc6ccccc6c(=O)c5c4)cc3)cc12]

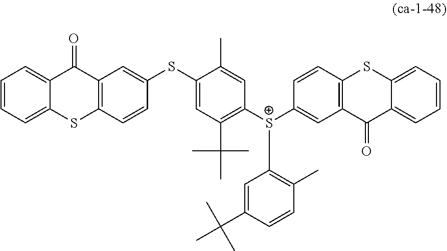 [SMILES: Cc1cc([S+](c2ccc3sc4ccccc4c(=O)c3c2)c2cc(C(C)(C)C)ccc2C)c(C(C)(C)C)cc1Sc1ccc2sc3ccccc3c(=O)c2c1]

As the cation represented by Formula (ca-2), specifically, a diphenyliodonium cation and a bis(4-tert-butylphenyl)iodonium cation are suitable exemplary examples.

As the cation represented by Formula (ca-3), specifically, cations represented by Formulae (ca-3-1) to (ca-3-6) are suitable exemplary examples.

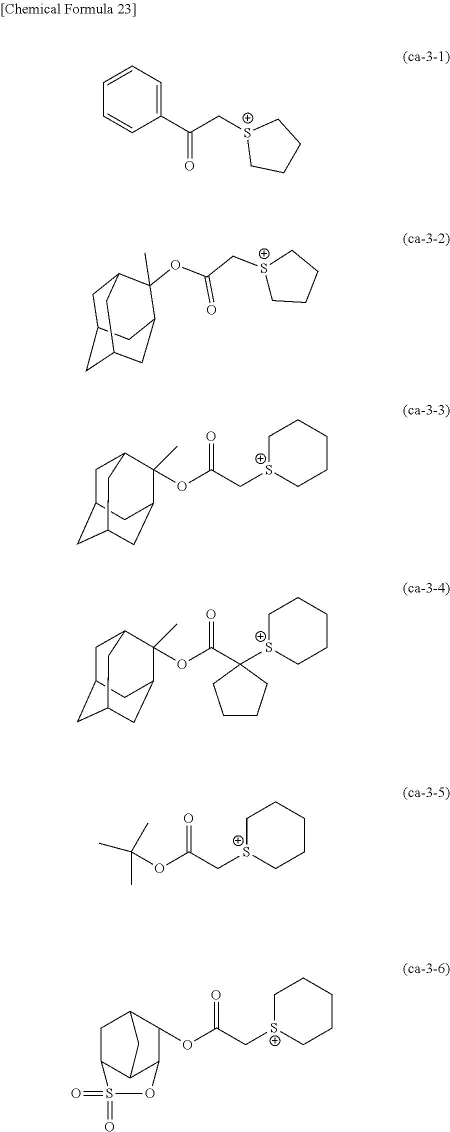 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

As the cation represented by Formula (ca-4), specifically, cations represented by Formulae (ca-4-l) and (ca-4-2) are suitable exemplary examples.

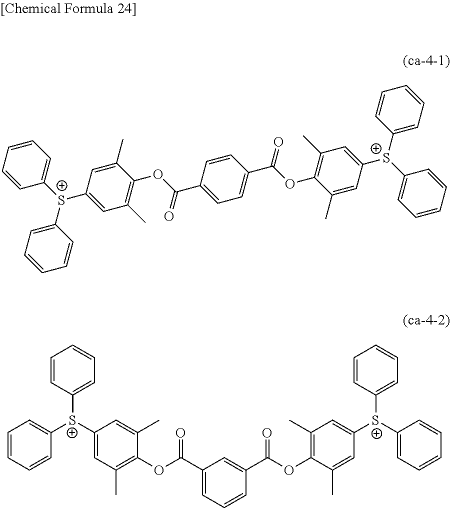 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

In addition, as the cation represented by Formula (ca-5), cations represented by General Formulae (ca-5-1) to (ca-5-3) are also preferable.

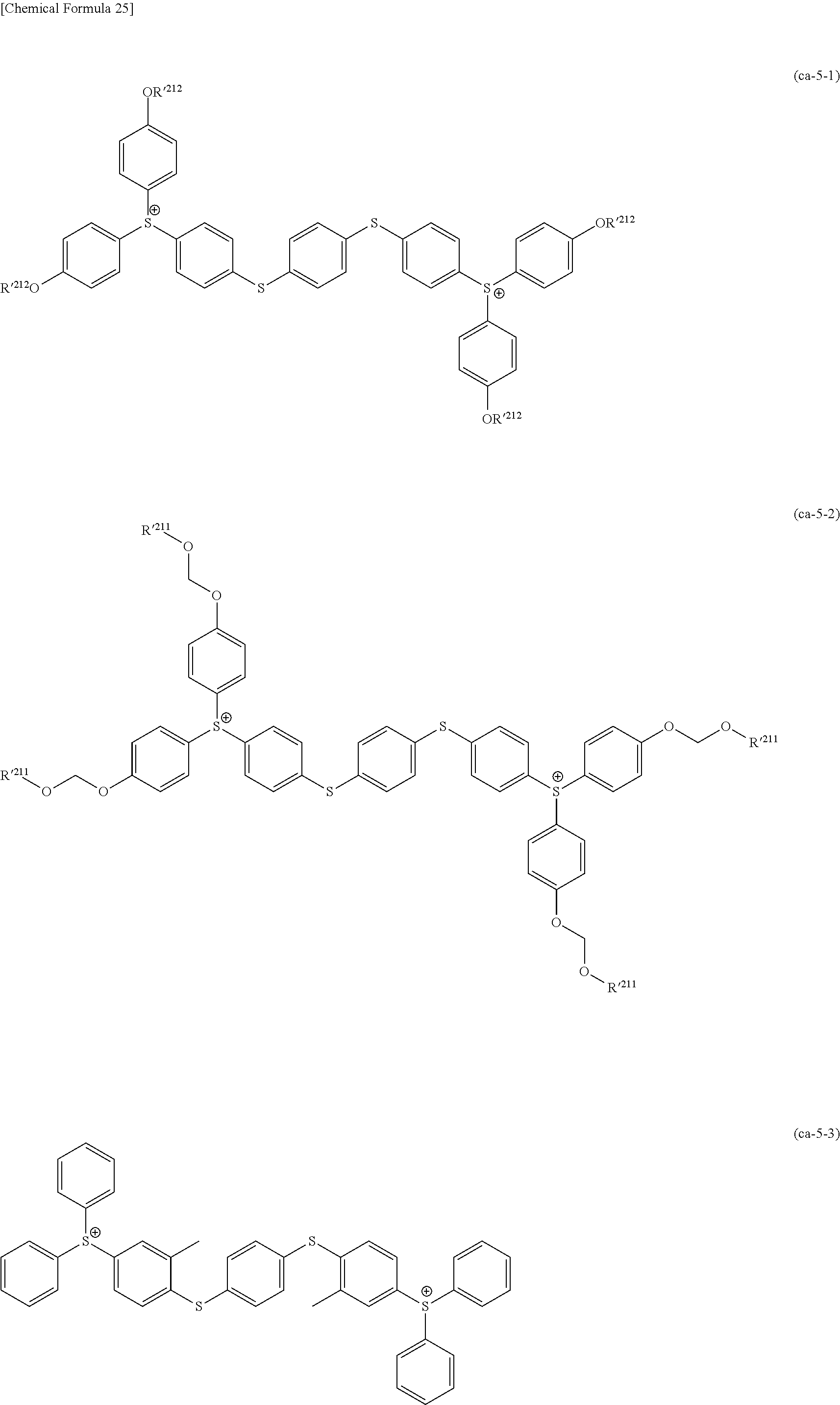

[In the Formulae, R′²¹² represents an alkyl group or a hydrogen atom. R′²¹¹ represents an alkyl group.]

Among the examples, as the cation moiety [(Q^{q+})_{1/q}], a cation represented by General Formula (ca-1) is preferable, a cation represented by any of Formulae (ca-1-1) to (ca-1-48) is more preferable, and a cation represented by Formula (ca-1-25), a cation represented by Formula (ca-1-29), a cation represented by Formula (ca-1-35), a cation represented by Formula (ca-1-47), or a cation represented by Formula (ca-1-48) is still more preferable.

Specific examples of the suitable component (I1) are shown below.

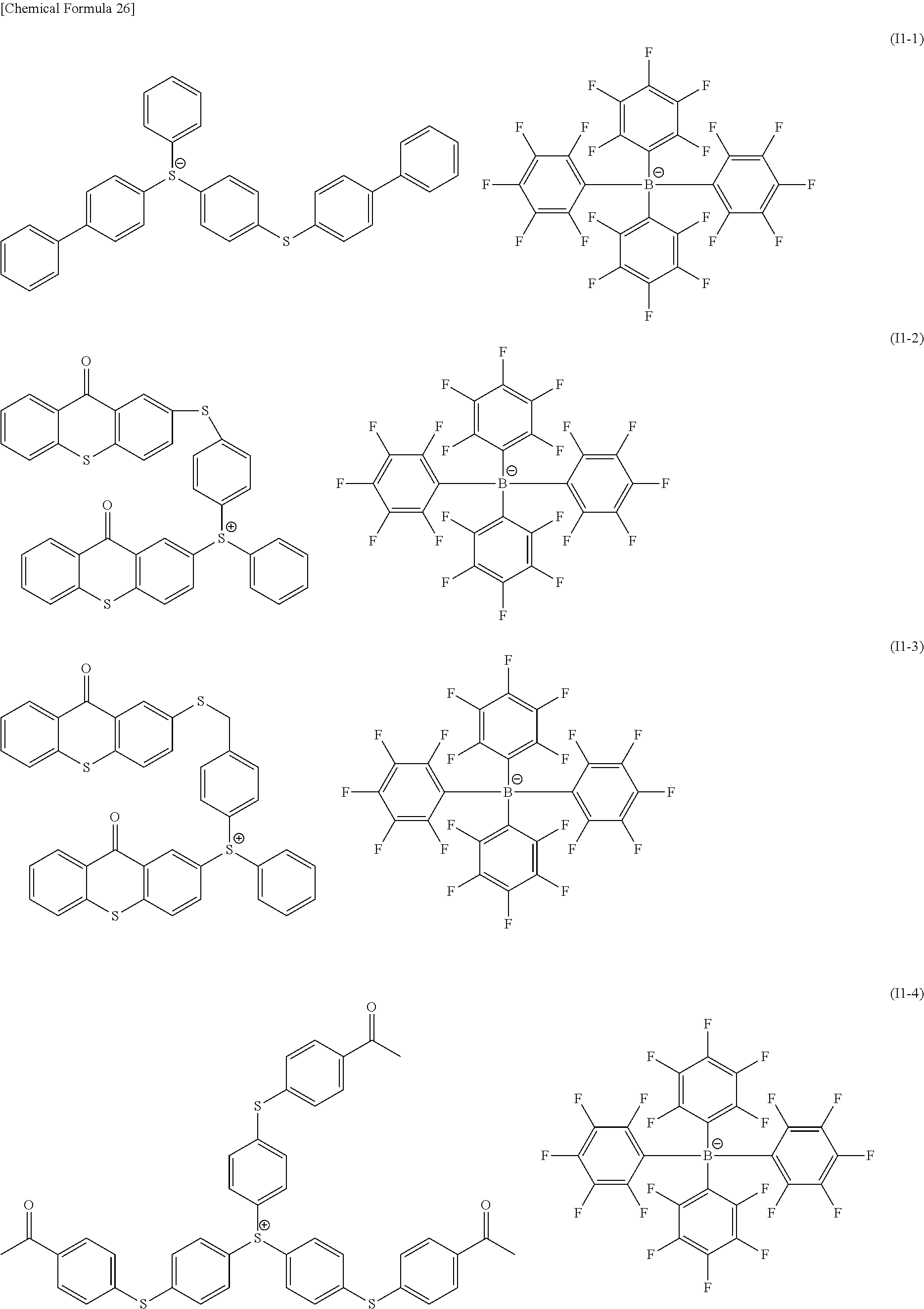

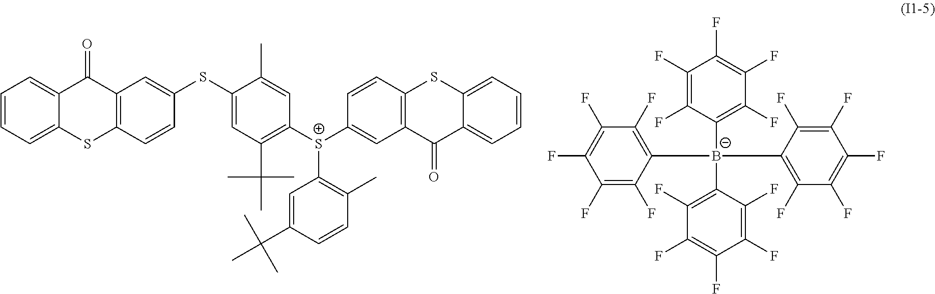 [SMILES: Cc1cc([S+](c2ccc3sc4ccccc4c(=O)c3c2)c2cc(C(C)(C)C)ccc2C)c(C(C)(C)C)cc1Sc1ccc2sc3ccccc3c(=O)c2c1 ; Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F]

<<Other cationic polymerization initiators>>

Examples of the cationic polymerization initiator other than the above-described component (I1) include a compound represented by General Formula (I2-1) or (I2-2) (hereinafter, referred to as “component (I2)”) and a compound represented by General Formula (I3-1) or (13-2) (hereinafter, referred to as “component (I3)”).

### Regarding Component (I2):

The component (I2) is a compound represented by General Formula (I2-1) or (I2-2).

Since a relatively strong acid is generated upon exposure to light from the component (I2), in a case where a pattern is formed using the photosensitive composition containing the component (I), sufficient sensitivity can be obtained and a favorable pattern can be formed.

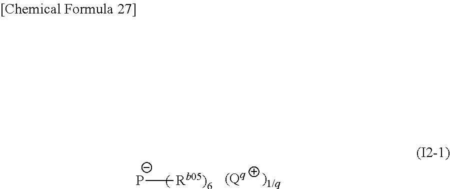

[In Formula, R^{b05} represents a fluorinated alkyl group which may have a substituent or a fluorine atom. A plurality of R^{b05}'s may be the same as or different from each other. q represents an integer of 1 or greater, and Q^{q+} represents a q-valent organic cation.]

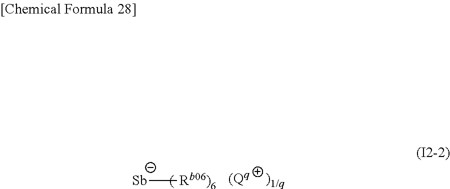

[In Formula, R^{b06} represents a fluorinated alkyl group which may have a substituent or a fluorine atom. A plurality of R^{b06}'s may be the same as or different from each other. q represents an integer of 1 or greater, and Q^{q+} represents a q-valent organic cation.]

### Anion Moiety

In Formula (I2-1), R^{b05} represents a fluorinated alkyl group which may have a substituent or a fluorine atom. A plurality of R^{b05}'s may be the same as or different from each other.

The fluorinated alkyl group as R^{b05} has preferably 1 to 10 carbon atoms, more preferably 1 to 8 carbon atoms, and still more preferably 1 to 5 carbon atoms. Specific examples thereof include an alkyl group having 1 to 5 carbon atoms, in which some or all hydrogen atoms have been substituted with fluorine atoms.

Among the examples, R^{b05} represents preferably a fluorine atom or a fluorinated alkyl group having 1 to 5 carbon atoms, more preferably a fluorine atom or a perfluoroalkyl group having 1 to 5 carbon atoms, and still more preferably a fluorine atom, a trifluoromethyl group, or a pentafluoroethyl group.

It is preferable that the anion moiety of the compound represented by Formula (I2-1) is an anion moiety represented by General Formula (b0-2a).

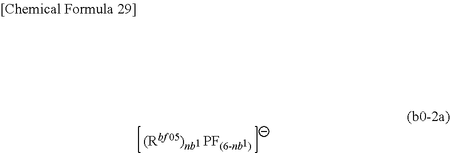

[In the Formula, R^{bf05} represents a fluorinated alkyl group which may have a substituent. nb¹ represents an integer of 1 to 5.]

In Formula (b0-2a), the fluorinated alkyl group which may have a substituent as R^{bf05} has the same definition as the fluorinated alkyl group which may have a substituent, described in the section of R^{b05}.

In Formula (b0-2a), nb¹ represents preferably an integer of 1 to 4, more preferably an integer of 2 to 4, and most preferably 3.

In Formula (I2-2). R^{b06} represents a fluorinated alkyl group which may have a substituent or a fluorine atom. A plurality of R^{b06}'s may be the same as or different from each other.

The fluorinated alkyl group as R^{b06} has preferably 1 to 10 carbon atoms, more preferably 1 to 8 carbon atoms, and still more preferably 1 to 5 carbon atoms. Specific examples thereof include an alkyl group having 1 to 5 carbon atoms, in which some or all hydrogen atoms have been substituted with fluorine atoms.

Among these, R^{b06} represents preferably a fluorine atom or a fluorinated alkyl group having 1 to 5 carbon atoms, more preferably a fluorine atom or a perfluoroalkyl group having 1 to 5 carbon atoms, and still more preferably a fluorine atom.
Cation moiety In Formula (I2-1) and Formula (I2-2), q represents an integer of 1 or greater, and Q^{q+} represents a q-valent organic cation.

Q^{q+} has the same definition as that for Q^{q+} in Formula (I1). Among the examples, Q represents preferably a cation represented by General Formula (ca-1), more preferably a cation represented by any of Formulae (ca-1-1) to (ca-1-48), and still more preferably a cation represented by Formula (ca-I-25), a cation represented by Formula (ca-1-29), a cation represented by Formula (ca-1-35), or a cation represented by Formula (ca-1-47).

Specific examples of the suitable component (I2) are shown below.

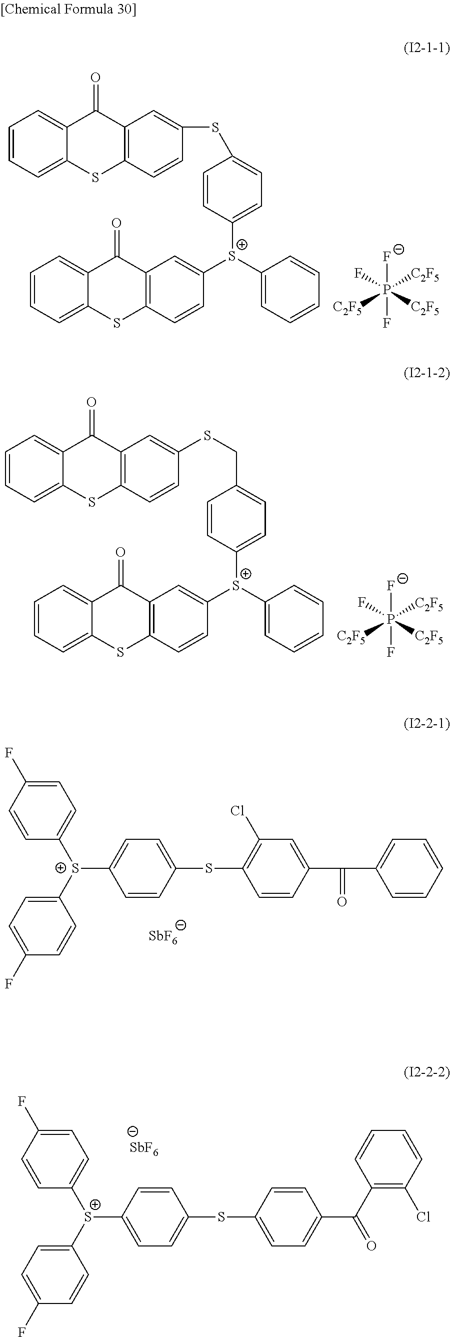

### Regarding Component (I3):

The component (I3) is a compound represented by General Formula (I3-1) or (13-2).

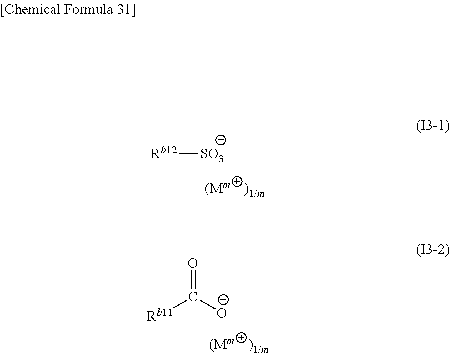

[In the Formulae, R^{b11} and R^{b12} represent a cyclic group which may have a substituent other than a halogen atom, a chain-like alkyl group which may have a substituent other than a halogen atom, or a chain-like alkenyl group which may have a substituent other than a halogen atom. m represents an integer of 1 or greater, and M^{m+}'s each independently represent an m-valent organic cation.]

### {Component (I3-1)}

### Anion Moiety

In Formula (I3-1), R^{b12} represents a cyclic group which may have a substituent other than a halogen atom, a chain-like alkyl group which may have a substituent other than a halogen atom, or a chain-like alkenyl group which may have a substituent other than a halogen atom, and examples thereof include groups having no substituent or having a substituent other than a halogen atom among the cyclic group, the chain-like alkyl group, and the chain-like alkenyl group as R′²⁰¹ described above.

It is preferable that R^{b12} represents a chain-like alkyl group which may have a substituent other than a halogen atom or an aliphatic cyclic group which may have a substituent other than a halogen atom.

The number of carbon atoms in the chain-like alkyl group is preferably 1 to 10 and more preferably 3 to 10. As the aliphatic cyclic group, a group (which may have a substituent other than a halogen atom) formed by removing one or more hydrogen atoms from adamantane, norbornane, isobornane, tricyclodecane, tetracyclododecane, or the like; or a group formed by removing one or more hydrogen atoms from camphor or the like is more preferable.

The hydrocarbon group as R^{b12} may have a substituent other than a halogen atom, and examples of the substituent are the same as the substituents other than a halogen atom, which may be included in the hydrocarbon group (such as an aromatic hydrocarbon group, an aliphatic cyclic group, or a chain-like alkyl group) as R^{b11} in Formula (I3-2).

The expression “may have a substituent other than a halogen atom” here excludes not only a case of having a substituent consisting of only a halogen atom but also a case of having a substituent having even one halogen atom (for example, a case where the substituent is a fluorinated alkyl group).

Specific preferred examples of the anion moiety of the component (I3-1) are shown below.

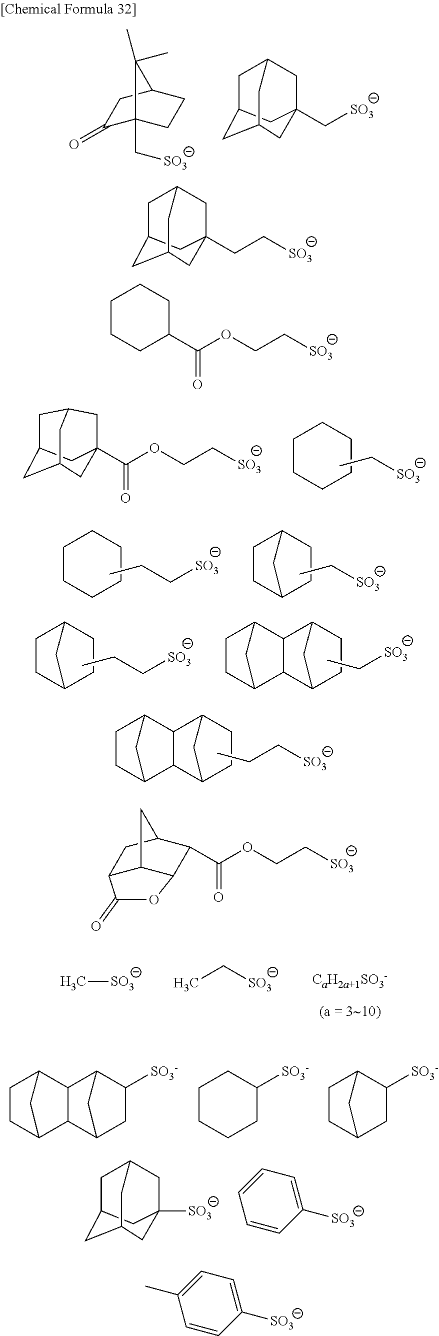

### Cation Moiety

In Formula (I3-1), M^{m+} represents an m-valent organic cation. Suitable examples of the organic cation as M^{m+} are the same as the cations each represented by Formulae (ca-1) to (ca-5). Among these, a cation represented by the Formula (ca-1) is more preferable. In addition, a sulfonium cation in which at least one of R²⁰¹, R²⁰², or R²⁰³ in General Formula (ca-1) represents an organic group (such as an aryl group, a heteroaryl group, an alkyl group, or an alkenyl group) which may have a substituent and has 16 or more carbon atoms is particularly preferable from the viewpoint of improving resolution or roughness characteristics.

As the substituent which may be included in the organic group, an alkyl group, a halogen atom, a halogenated alkyl group, a carbonyl group, a cyano group, an amino group, an oxo group (═O), an aryl group, and groups represented by Formulae (ca-r-1) to (ca-r-10) are exemplary examples, as described above.

The number of carbon atoms in the above-described organic group (such as an aryl group, a heteroaryl group, an alkyl group, and an alkenyl group) is preferably in a range of 16 to 25, more preferably in a range of 16 to 20, and particularly preferably in a range of 16 to 18. Suitable examples of the organic cation as M^{m+} include cations each represented by Formulae (ca-1-25), (ca-1-26), (ca-1-28) to (ca-1-36), (ca-1-38), (ca-1-46), and (ca-1-47), and among these, a cation represented by Formula (ca-1-29) is particularly preferable.

### (Component (I3-2))

### Anion Moiety

In Formula (I3-2), R^{b11} represents a cyclic group which may have a substituent other than a halogen atom, a chain-like alkyl group which may have a substituent other than a halogen atom, or a chain-like alkenyl group which may have a substituent other than a halogen atom, and examples thereof include groups having no substituent or having a substituent other than a halogen atom among the cyclic group, the chain-like alkyl group, and the chain-like alkenyl group described in the section of R′²⁰¹ above.

Among these, it is preferable that R^{b11} represents an aromatic hydrocarbon group which may have a substituent other than a halogen atom, an aliphatic cyclic group which may have a substituent other than a halogen atom, and a chain-like alkyl group which may have a substituent other than a halogen atom. As the substituents which may be included in these groups, a hydroxyl group, an oxo group, an alkyl group, an aryl group, a lactone-containing cyclic group, an ether bond, an ester bond, and a combination thereof are exemplary examples.

In a case where an ether bond or an ester bond is included as the substituent, the substituent may be bonded through an alkylene group, and linking groups represented by General Formulae (y-a1-1) to (y-a1-7) are preferable as the substituent in this case.

Further, in General Formulae (y-a1-1) to (y-a1-7), V′¹⁰¹ in General Formulae (y-a1-1) to (y-a1-7) is bonded to R^{b11} of Formula (I3-2).

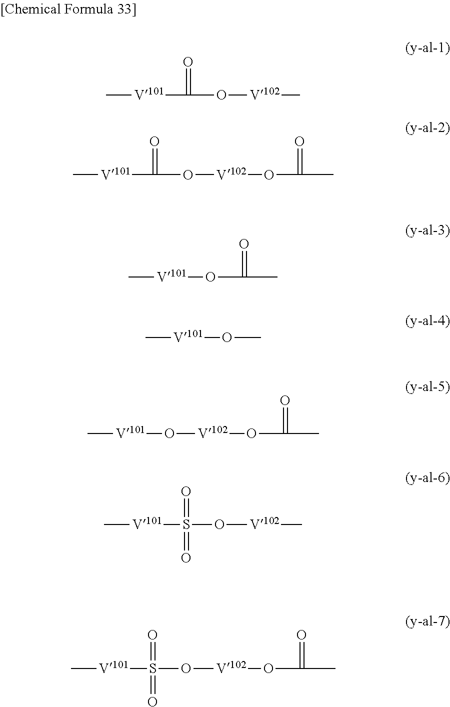

[In the Formulae, V′¹⁰¹ represents a single bond or an alkylene group having 1 to 5 carbon atoms. V′¹⁰² represents a divalent saturated hydrocarbon group having 1 to 30 carbon atoms.]

As the divalent saturated hydrocarbon group as V′¹⁰², an alkylene group having 1 to 30 carbon atoms is preferable, an alkylene group having 1 to 10 carbon atoms is more preferable, and an alkylene group having 1 to 5 carbon atoms is still more preferable.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH)—, —C(CH₃)₂—, —C(CH₃(CH₂CH₃)—, —C(CH₃)(CH₂CH₂CH)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

Further, some methylene groups in the alkylene groups as V′¹⁰¹ and V′¹⁰² may be substituted with a divalent aliphatic cyclic group having 5 to 10 carbon atoms. As the aliphatic cyclic group, a divalent group in which one hydrogen atom has been further removed from the cyclic aliphatic hydrocarbon group (a monocyclic alicyclic hydrocarbon group or a polycyclic alicyclic hydrocarbon group) as R′²⁰¹ is preferable, and a cyclohexylene group, a 1,5-adamantylene group, or a 2,6-adamantylene group is more preferable.

As the aromatic hydrocarbon group, a phenyl group or a naphthyl group is more preferable.

As the aliphatic cyclic group, a group formed by removing one or more hydrogen atoms from a polycycloalkane such as adamantane, norbornane, isobornane, tricyclodecane, and tetracyclododecane is more preferable.

The number of carbon atoms in the above-described chain-like alkyl group is preferably 1 to 10, and specifically, a linear alkyl group such as a methyl group, an ethyl group, a propyl group, a butyl group, a pentyl group, a hexyl group, a heptyl group, an octyl group, a nonyl group, and a decyl group; and a branched alkyl group such as a 1-methylethyl group, a 1-methylpropyl group, a 2-methylpropyl group, a I-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group are exemplary examples.

It is preferable that R^{b11} represents a cyclic group which may have a substituent other than a halogen atom.

Specific preferred examples of the anion moiety of the component (I3-2) are shown below.

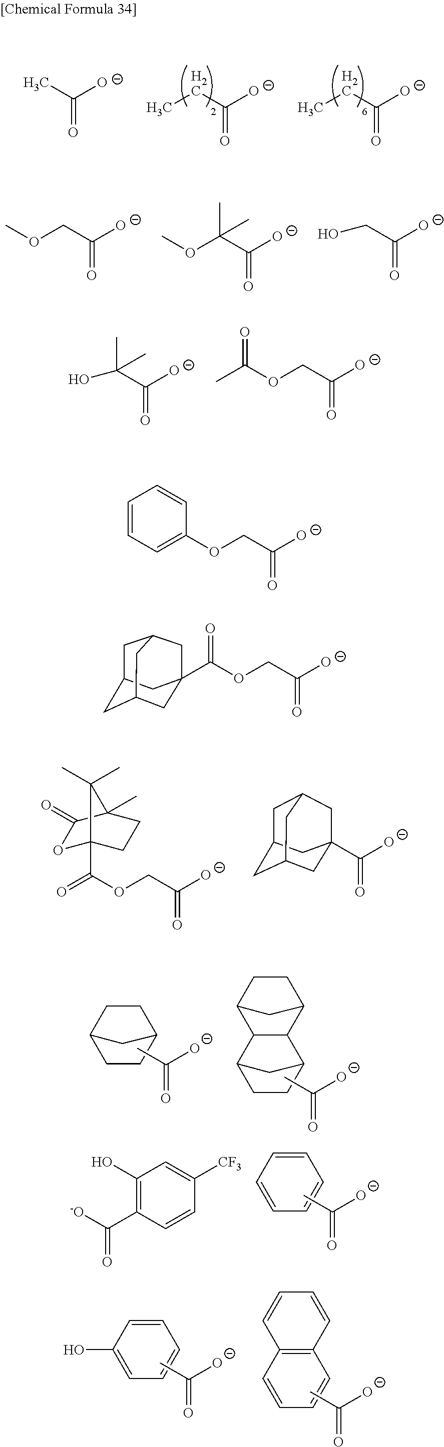

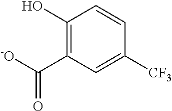

### Cation Moiety

In Formula (I3-2), M^{m+} represents an m-valent organic cation and has the same definition as that for M^{m+} in Formula (I3-1).

From the viewpoint of high elasticity of a resin film and ease of forming a fine structure without residues, it is preferable that the component (I) is a cationic polymerization initiator which generates an acid having a pKa (acid dissociation constant) of −5 or less upon exposure to light. It is possible to obtain high sensitivity upon exposure by using a cationic polymerization initiator that generates an acid having a pKa of more preferably −6 or less and still more preferably −8 or less. The lower limit value of the pKa of the acid generated from the component (I) is preferably −15 or more. The sensitivity is likely to be increased by using a cationic polymerization initiator which generates an acid having a pKa in the above-described suitable range.

Here, the term “pKa (acid dissociation constant)” is typically used as an index showing the acid strength of a target substance. The pKa in the present specification is a value obtained under a temperature condition of 25° C. In addition, the pKa value can be acquired by performing measurement according to a known technique. In addition, calculated values obtained by using a known software such as “ACD/Labs” (trade name, manufactured by Advanced Chemistry Development Inc.) can be used.

Specific examples of the suitable component (I3) are shown below.

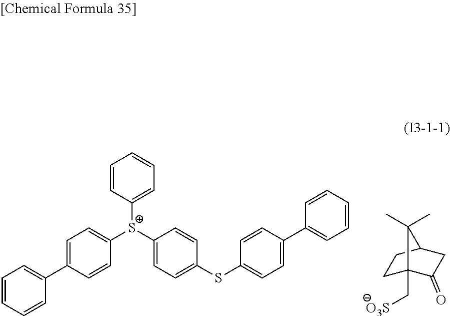

The component (P) may be used alone or in combination of two or more kinds thereof.

In the photosensitive composition used in the present embodiment, it is preferable that the component (I) is at least one selected from the group consisting of the component (I1), the component (I2), and the component (I3).

In the photosensitive composition used in the present embodiment, a content of the component (I) is preferably 0.05 to 5 parts by mass, more preferably 0.1 to 3 parts by mass, still more preferably 0.15 to 3 parts by mass, and particularly preferably 0.2 to 1 part by mass in a case where the total mass of the component (A) is set to 100 parts by mass.

In a case where the content of the component (I) is more than or equal to the lower limit value of the above-described preferred range, sufficient sensitivity is obtained, and lithography characteristics of the pattern are further improved. In addition, the hardness of the resin cured film is further increased. On the other hand, in a case of being less than or equal to the upper limit value of the above-described preferred range, the sensitivity is appropriately controlled and a pattern having a favorable shape is easily obtained.

### <Optional Components>

The photosensitive composition used in the present embodiment may contain, as necessary, other components (optional components) in addition to the above-described component (A) and component (I).

In the photosensitive composition according to the embodiment, as desired, it is possible to optionally add and contain miscible additives such as a metal oxide (M), a sensitizer component, a silane coupling agent, a solvent, an additive resin for improving film performance, a dissolution inhibitor, a basic compound, a plasticizer, a stabilizer, a colorant, and a halation-preventing agent.

### <<Metal Oxide (M)>>

The photosensitive composition used in the present embodiment may further contain the metal oxide (M) (hereinafter, also referred to as “component (M)”) in addition to the component (A) and the component (I), because a cured film having increased hardness is easily obtained. Further, in a case where the photocurable composition contains the component (M) in combination with other components, a high-resolution pattern having a satisfactory shape can be formed.

As the component (M), oxides of metals such as silicon (metallic silicon), titanium, zirconium, and hafnium are exemplary examples. Among these, an oxide of silicon is preferable. In addition, it is particularly preferable to use silica.

Further, the shape of the component (M) is preferably particulate. Such a particulate component (M) preferably includes a group consisting of particles having a volume average particle diameter of 5 to 40 nm, more preferably includes a group consisting of particles having a volume average particle diameter of 5 to 30 nm, and still more preferably includes a group consisting of particles having a volume average particle diameter of 10 to 20 nm.

### <<Sensitizer Component>>

The photosensitive composition used in the present embodiment may further contain a sensitizer component.

The sensitizer component is not particularly limited as long as it can absorb energy from exposure and transfer the energy to other substances.

As the sensitizer component, specifically, benzophenone-based photosensitizers such as benzophenone and p,p′-tetramethyldiaminobenzophenone, carbazole-based photosensitizers, acetophene-based photosensitizers, naphthalene-based photosensitizers such as 1,5-dihydroxynaphthalene, phenol-based photosensitizers, anthracene-based photosensitizers such as 9-ethoxyanthracene, and known photosensitizers such as biacetyl, eosin, rose bengal, pyrene, phenothiazine, and anthrone can be used.

### <<Solvent>>

The photosensitive composition used in the present embodiment may further contain a solvent (hereinafter, may be referred to as “component (S)”).

As the component (S), for example, lactones such as γ-butyrolactone; ketones such as acetone, methyl ethyl ketone (MEK), cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond, such as 2-methoxybutyl acetate, 3-methoxybutyl acetate. 4-methoxybutyl acetate, ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monoethylether, monopropylether, or monobutylether or monophenylether of any of the polyhydric alcohols or the compounds having an ester bond [among these, propylene glycol monomethyl ether acetate (PGMEA), or propylene glycol monomethyl ether (PGME) is preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylnethylether, diphenylether, dibenzylether, phenetole, butylphenylether, ethylbenzene, diethylbenzene, pentylbenzene, isopropylbenzene, toluene, xylene, cymene, and mesitylene; and dimethylsulfoxide (DMSO) are exemplary examples.

The component (S) may be used alone or in the form of a mixed solvent of two or more kinds thereof.

An amount of the component (S) used in a case of being contained is not particularly limited, and is appropriately set according to the thickness of the coating film at a concentration at which the photosensitive composition can be applied to a substrate or the like without dripping.

For example, the component (S) can be used so that the solid content concentration is set to 50% by mass or greater, or the component (S) can be used so that the solid content concentration is set to 60% by mass or greater.

In addition, an aspect in which the component (S) is not substantially contained (that is, an aspect in which the concentration of solid contents is 100% by mass) can be adopted.

### (Laminate)

A second aspect of the present invention relates to the laminate of the support and the resist layer, in which the support consists of a polyethylene terephthalate film having a light transmittance of 85% or more at a wavelength of 365 nm and a haze value of 1.0% or less when irradiated with light having a wavelength of 365 nm, and the resist layer consists of a photosensitive layer formed of a negative photosensitive composition.

The laminate according to the second aspect is used for producing a hollow structure consisting of a concave portion that is surrounded by a substrate and a side wall formed on the substrate and a top plate portion that blocks an opening surface of the concave portion.

A description of the laminate is the same as the <Laminate> described in (production method for hollow structure) described above.

### EXAMPLES

Hereinafter, the present invention will be described in more detail with reference to examples, but the present invention is not limited to these examples.

In the present example, the following support and negative photosensitive composition were used.

### <<Support>>

As the support, the following PET (1) to (7), which are polyethylene terephthalate films having a thickness of 50 μm, were each used.

The light transmittance and the haze value of the support were measured as follows. These results are shown in Table 1.

### Measuring Method of Light Transmittance:

An ultraviolet-visible-near infrared spectrophotometer UV-3600 (manufactured by Shimadzu Corporation) is used in the light transmittance of the support, the total light transmittance (%) in a wavelength range of 200 to 800 nm is measured (baseline correction: air blank), and the light transmittance (%) at a wavelength of 360 nm was obtained.

### Measuring Method of Haze Value:

The haze value (%) of the support was measured by using a haze meter COH7700 (manufactured by Nippon Denshoku Industries Co., Ltd.) based on JIS K 7361-1, and a haze value (%) when irradiated with light having a wavelength of 365 nm was obtained.

TABLE 1

| Polyethylene terephthalate | Light transmittance | Haze value |
|---|---|---|
| film | (%) | (%) |
| PET (1) | 87.08 | 0.54 |
| PET (2) | 87.08 | 0.67 |
| PET (3) | 85.85 | 0.58 |
| PET (4) | 85.59 | 0.95 |
| PET (5) | 85.72 | 1.00 |
| PET (6) | 85.87 | 4.60 |
| PET (7) | 82.04 | 7.33 |

### <<Negative Photosensitive Composition>>

Each component shown in Table 2 was mixed and dissolved, and the mixture was filtered by using a PTFE filter (pore size: 1 μm, manufactured by PALL Corporation) to prepare a negative photosensitive composition (RN) which is a MEK solution containing 84% by mass of solid contents.

TABLE 2

| | Component (A) | Component (I) | Other components | |
|---|---|---|---|---|
| Negative | (A)-1 | (I)-1 | (D)-1 | (SC)-1 |
| photosensitive | [100] | [3.0] | [1.0] | [5.0] |
| composition (RN) | | | | |

In Table 2, each abbreviation has the following meaning. The numerical values in [ ] are the blending amounts (parts by mass, in terms of solid content) of the respective components.
(A)-1: A compound represented by Chemical Formula (A1-1). Trade name “jER-157S70”, manufactured by Mitsubishi Chemical Corporation.
(I)-1: cationic polymerization initiator represented by Chemical Formula (I2-2-2).
(D)-1: sensitizer, α-naphthol.
(SC)-1: A compound represented by Chemical Formula (SC-1).

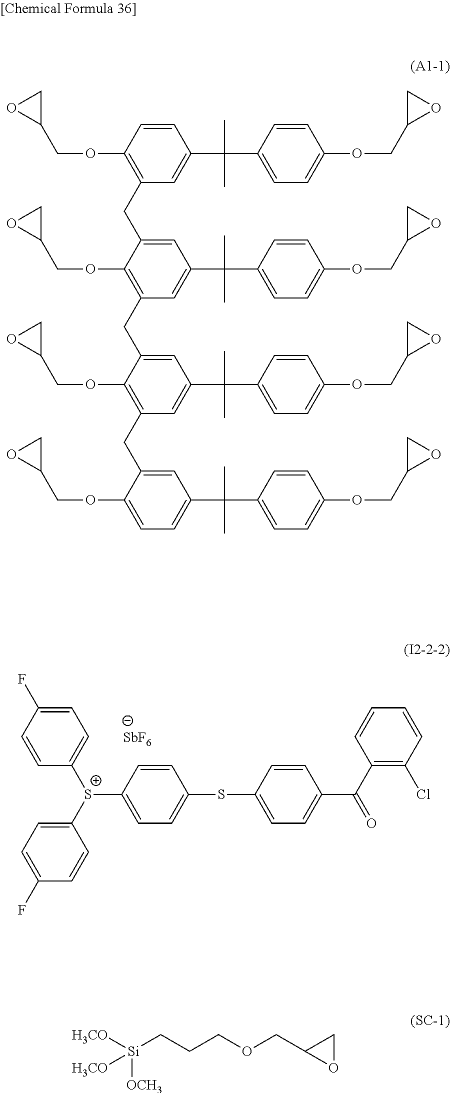 [SMILES: CC(C)(c1ccc(OCC2CO2)cc1)c1ccc(OCC2CO2)c(Cc2cc(C(C)(C)c3ccc(OCC4CO4)cc3)cc(Cc3cc(C(C)(C)c4ccc(OCC5CO5)cc4)cc(Cc4cc(C(C)(C)c5ccc(OCC6CO6)cc5)ccc4OCC4CO4)c3OCC3CO3)c2OCC2CO2)c1 ; O=C(c1ccc(Sc2ccc([S+](c3ccc(F)cc3)c3ccc(F)cc3)cc2)cc1)c1ccccc1Cl ; "SbF6" ; CO[Si](CCCOCC1CO1)(OC)OC]

### <Production of Laminate>

By using the PET (1) to (7) that are the above-described support and the negative photosensitive composition (RN), a laminate was produced.

### Example 1

The PET (1) was used as a support, and the negative photosensitive composition (RN) was applied onto the PET (1) having a thickness of 50 μm using an applicator, and a resist layer was formed by performing baking treatment at a temperature of 90° C. for 5 minutes, thereby producing a laminate of the PET (1) having a thickness of 50 μm and the resist layer having a film thickness of 20 μm.

### Examples 2 to 5 and Comparative Examples 1 to 2

Except that the PET (1) as the support is each changed to the PET (2) to (7), each laminate of each of the PET (2) to (7) having a thickness of 50 μm and a resist layer having a film thickness of 20 μm was produced in the same manner as that in Example 1.

As the cover film, a polyethylene terephthalate film (a PET(0)) other than the PET (1) to (7) was used.

The PET (0) was bonded to a surface of the resist layer opposite to the support in each of the above-produced laminates, so that a dry film resist was produced.

### <Formation of Negative Pattern>

The PET (0) that is a cover film was peeled off from the dry film resist to form a laminate state (the laminate of the support and the resist layer), and the laminate was attached to a Si substrate such that the resist layer was in contact with the Si substrate.

An attaching operation was performed by using a laminator at 90° C., a pressure of 0.3 MPa, and a processing speed of 0.5 m/min.

Next, the resist layer in the laminate attached to the Si substrate was exposed to 400 mJ/cm² in terms of i-ray via the support by a ghi broadband exposure machine.

Next, baking treatment with respect to the laminate after the exposure (post-exposure bake (PEB)) was performed at 90° C. for 300 seconds.

Next, the support was peeled off from the laminate after the PEB, and the resist layer after the baking treatment was developed by immersing the resist layer in propylene glycol monomethyl ether acetate (PGMEA) at 23° C. for 2 minutes to form a negative pattern.

### [Evaluation of Negative Pattern Shape]

A target negative pattern (LS pattern having a line width of 20 μm and a pitch width of 40 μm) formed in the above-described <formation of negative pattern> was evaluated according to the following evaluation standard by observation with an SEM image (magnification: 1000 times). The results are shown in Table 3 as “shape”.

FIG. 3 is a photograph of a height direction cross section of a negative pattern, and shows an evaluation standard in an evaluation of a negative pattern shape. In FIG. 3, line portions 90 are formed at constant intervals (pitches).

### Evaluation Standard

A: a state in which a side surface 92 of the line portion 90 is smooth without roughness
B: a state in which slight roughness was observed on the side surface 92 of the line portion 90

### [Evaluation of Defect of Negative Pattern Surface]

A surface roughened state of the target negative pattern (the LS pattern having a line width of 20 μm and a pitch width of 40 μm) formed in the above-described <Formation of negative pattern> was evaluated according to the following evaluation standard by observation with an optical microscope (magnification: 20 times). The results are shown in Table 3 as “Defect”.

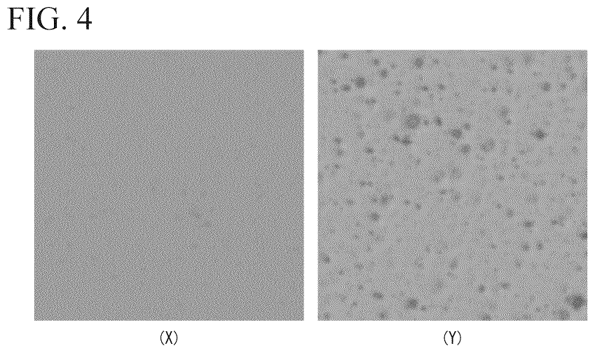

FIG. 4 is a photograph of a line portion surface of a negative pattern, and shows an evaluation standard in an evaluation of a defect on a negative pattern surface.

A surface roughened state (X) of the pattern is a state in which the surface roughening is small, which is satisfactory.

In a surface roughened state (Y) of the pattern, the surface roughening is remarkable, which is not satisfactory.

### Evaluation Standard

A: the surface roughened state (X) of the pattern or a state close to the surface roughened state (X)
B: a state between the surface roughened state (X) and the surface roughened state (Y) of pattern
C: the surface roughened state of the pattern (Y) or a state close to the surface roughened state (Y)

TABLE 3

| | Polyethylene terephthalate | | |
|---|---|---|---|
| Laminate | film | Shape | Defect |
| Example 1 | PET (1) | A | A |
| Example 2 | PET (2) | A | A |
| Example 3 | PET (3) | A | A |
| Example 4 | PET (4) | A | A |
| Example 5 | PET (5) | A | A |
| Comparative Example 1 | PET (6) | B | B |
| Comparative Example 2 | PET (7) | B | C |

From the results shown in Table 3, it was confirmed that, in a case where the laminate of Examples 1 to 5 is used, the optical influence was suppressed as compared with a case where the laminate of Comparative Examples 1 and 2 is used, so that the lithography characteristics (shape and defect reduction) of the pattern could be further improved.

### <Production of Hollow Structure>

The negative photosensitive composition (RN) was uniformly applied onto the Si substrate using an applicator, and was subjected to the baking treatment (PAB) at a heating temperature of 90° C. for 5 minutes to form a photosensitive film (a film thickness: 20 μm).

Next, the photosensitive film was exposed with an irradiation amount of 200 mJ/cm² (ghibroadband) using a Suss MABA8 Gen4 pro aligner.

Next, the photosensitive film after the exposure was subjected to post-exposure heating on a hot plate at 90° C. for 5 minutes, thereby obtaining a pre-cured film.

Next, paddle development was performed at 23° C. for 120 seconds by using PGMEA as a developing solution, and after drying by blowing off, the pre-cured film was heated at 200° C. for 1 hour in a nitrogen atmosphere to be cured.

As described above, a substrate with a wall (concave portion), in which a concave portion pattern where a square periphery of 1170 m in length and 1500 μm in width was surrounded by the side walls (Wall) having a width of 50 μm consisting of the cured film was formed, was obtained on the Si substrate.

Next, a laminate of a resist layer consisting of a photosensitive layer in which a film thickness was adjusted to 30 μm by using the negative photosensitive composition (RN) and of a support consisting of the PET (1) that is a polyethylene terephthalate film having a thickness of 50 μm, was disposed (laminated) on an upper surface of the side wall (Wall) such that an opening surface of the concave portion in the substrate with a wall was blocked.

Lamination conditions when the laminate was disposed on the upper surface of the side wall were set to a temperature of 90° C., a pressure of 0.3 MPa, and a processing speed of 0.5 m/min. In this case, the laminate was disposed such that the resist layer faces the Si substrate with the side wall sandwiched therebetween, to form a hollow sealed space surrounded by the Si substrate, the side wall, and the resist layer.

Next, the resist layer constituting the laminate was selectively exposed to 200 mJ/cm² (in terms of i-ray) via a predetermined mask pattern using a Suss MABA8 Gen4 pro aligner through a support (PET (1)).

Next, the laminate after the selective exposure was subjected to post-exposure heating on a hot plate at a temperature of 90° C. for 5 minutes.

After that, the support (PET (1)) was peeled off from the resist layer in the laminate.

Next, the resist layer after the post-exposure heating was subjected to paddle development at 23° C. for 120 seconds by using PGMEA as a developing solution, thereby forming a roof pattern serving as a top plate portion (a roof that blocks the opening surface of the concave portion).

The roof pattern was further cured by performing a heat treatment at a temperature of 200° C. for 60 minutes in an oven to produce a hollow structure in which the side wall (Wall) and the top plate portion were integrated (a cavity size: 1170 μm in length×1500 μm in width×50 μm in height).

In the above-described <producing of hollow structure>, in a case where the top plate portion is formed, a pattern having fine dimensions can be formed with good lithography characteristics (shape and defect reduction), and deformation or the like is suppressed, so that the hollow structure can be stably produced.

Although preferred examples of the present invention are described above, the present invention is not limited to these examples. It is possible to add other configurations or to omit, replace, or modify the configurations described herein without departing from the spirit of the present invention. The present invention is not limited by the description above, but is limited only by the appended claims.

### REFERENCE SIGNS LIST

10: Substrate
20: Side wall
30: Resist layer
40: Cured body
50: Support
60: Photomask
80: Laminate
100: Hollow structure

What is claimed is:

1. A production method for a hollow structure consisting of a concave portion that is surrounded by a substrate and a side wall formed on the substrate and a top plate portion that blocks an opening surface of the concave portion, the production method comprising:
obtaining the concave portion in which the side wall is formed on the substrate; and
obtaining the hollow structure by forming the top plate portion on the side wall,
wherein at least one of the side wall or the top plate portion is formed by using a laminate of a support and a resist layer,
the support consists of a polyethylene terephthalate film having a light transmittance of 85% or more at a wavelength of 365 nm and a haze value of 1.0% or less when irradiated with light having a wavelength of 365 nm,
the resist layer consists of a photosensitive layer formed of a negative photosensitive composition, and
when the at least one of the side wall or the top plate portion is formed by using the laminate, an operation of exposing the resist layer via the support and developing the laminate after the exposure with a developing solution containing an organic solvent to form a negative pattern is performed.

2. The production method for a hollow structure according to claim 1, wherein the support consists of a polyethylene terephthalate film having a light transmittance of 85% or more at a wavelength of 365 nm and a haze value of 0.90% or less when irradiated with light having a wavelength of 365 nm.

3. The production method for a hollow structure according to claim 1, wherein the negative photosensitive composition contains an epoxy group-containing compound and a cationic polymerization initiator.

4. A laminate of a support and a resist layer,
wherein the support consists of a polyethylene terephthalate film having a light transmittance of 85% or more at a wavelength of 365 nm and a haze value of 1.0% or less when irradiated with light having a wavelength of 365 nm,
the resist layer consists of a photosensitive layer formed of a negative photosensitive composition, and
the laminate is used for producing a hollow structure consisting of a concave portion that is surrounded by a substrate and a side wall formed on the substrate and a top plate portion that blocks an opening surface of the concave portion.
